(19) United States
(12) Patent Application Publication
(10) Pub. No.: US 2015/0263044 A1
(43) Pub. Date: Sep. 17, 2015

(54) NONVOLATILE SEMICONDUCTOR STORAGE DEVICE AND METHOD OF MANUFACTURING THE SAME

(71) Applicant: KABUSHIKI KAISHA TOSHIBA, Minato-ku (JP)

(72) Inventors: Hiroyuki YAMASAKI, Chiba (JP); Hisataka MEGURO, Yokkaichi (JP)

(73) Assignee: KABUSHIKI KAISHA TOSHIBA, Minato-ku (JP)

(21) Appl. No.: 14/644,992

(22) Filed: Mar. 11, 2015

Related U.S. Application Data
(60) Provisional application No. 61/952,722, filed on Mar. 13, 2014.

(51) Int. Cl. H01L 27/12; H01L 29/16; H01L 21/285; H01L 29/45; H01L 29/06; H01L 21/02; H01L 27/115; H01L 29/04

(52) U.S. Cl. CPC H01L 27/1207; H01L 27/11521; H01L 27/1157; H01L 29/16; H01L 29/04; H01L 29/456; H01L 29/0649; H01L 21/02381; H01L 21/02428; H01L 21/02532; H01L 21/02592; H01L 21/02636; H01L 21/02667; H01L 21/28518; H01L 21/0217

(57) ABSTRACT

A semiconductor storage device includes a semiconductor substrate; a first layer memory cell having the semiconductor substrate serving as a channel layer; a semiconductor layer provided along the first layer memory cell via an insulating film; and a second layer memory cell having the semiconductor layer serving as a channel layer, the semiconductor layer of the second memory cell layer comprises a polycrystalline silicon film including a single crystal region.

### CROSS-REFERENCE TO RELATED APPLICATION(S)

This application is based upon and claims the benefit of priority from U.S. Provisional Patent Application No. 61/952,722, filed on, Mar. 13, 2014 the entire contents of which are incorporated herein by reference.

### FIELD

Embodiments disclosed herein generally relate to a semiconductor storage device and a method of manufacturing the same.

### BACKGROUND

In a NAND flash memory device which is one example of a semiconductor storage device, attempts are made to increase integration density by stacking, for example, multiple layers each having a planar memory cell region formed therein. In such case, the memory cell in the lowermost layer may be configured so that the semiconductor substrate serves as an active layer. In the memory cell of the second layer or higher layers may use a polycrystalline silicon film for example as an active layer.

In such case, a polycrystalline silicon film is used as a channel layer in the memory cell layer located in the second layer or higher layers. It becomes increasingly difficult for cell current to flow through a channel layer formed of a polycrystalline silicon film as the integration density increases, since the size of the grain boundary of a polycrystalline silicon film is large relative to the channel width. The mobility of the channel layer of a polycrystalline silicon film being lower than the mobility of a single crystal silicon film or traps in the grain boundaries are some of the causes of this problem.

### BRIEF DESCRIPTION OF THE DRAWINGS

FIG. 1 pertains to a first embodiment and is one example of an equivalent circuit of an electrical configuration of a semiconductor device.

FIG. 2 is one example of a plan view schematically illustrating a memory cell region.

FIG. 3 is one example of a vertical cross-sectional side view schematically illustrating electrical elements of a portion taken along line 3-3 of FIG. 2.

FIG. 4 is one example of a vertical cross-sectional side view taken along line 4-4 of FIG. 2 illustrating a specific structure of FIG. 3.

FIG. 5 illustrates one phase of a manufacturing process flow and is one example of a vertical cross-sectional side view taken along line 4-4 of FIG. 2 (Part 1).

FIG. 6 illustrates one phase of a manufacturing process flow and is one example of a vertical cross-sectional side view taken along line 4-4 of FIG. 2 (Part 2).

FIG. 7 illustrates one phase of a manufacturing process flow and is one example of a vertical cross-sectional side view taken along line 4-4 of FIG. 2 (Part 3).

FIG. 8 illustrates one phase of a manufacturing process flow and is one example of a vertical cross-sectional side view taken along line 4-4 of FIG. 2 (Part 4).

FIG. 9 illustrates one phase of a manufacturing process flow and is one example of a vertical cross-sectional side view taken along line 4-4 of FIG. 2 (Part 5).

FIG. 10 illustrates one phase of a manufacturing process flow and is one example of a vertical cross-sectional side view taken along line 4-4 of FIG. 2 (Part 6).

FIG. 11 illustrates one phase of a manufacturing process flow of a second embodiment and is one example of a vertical cross-sectional side view taken along line 4-4 of FIG. 2 (Part 1).

FIG. 12 illustrates one phase of a manufacturing process flow and is one example of a vertical cross-sectional side view taken along line 4-4 of FIG. 2 (Part 2).

FIG. 13 illustrates one phase of a manufacturing process flow and is one example of a vertical cross-sectional side view taken along line 4-4 of FIG. 2 (Part 3).

FIG. 14 illustrates one phase of a manufacturing process flow and is one example of a vertical cross-sectional side view taken along line 4-4 of FIG. 2 (Part 4).

FIG. 15 is one example of a schematic vertical cross-sectional side view taken along line 3-3 of FIG. 2 illustrating a third embodiment.

FIG. 16 illustrates one phase of a manufacturing process flow and is one example of a schematic vertical cross-sectional side view taken along line 3-3 of FIG. 2 (Part 1).

FIG. 17 illustrates one phase of a manufacturing process flow and is one example of a schematic vertical cross-sectional side view taken along line 3-3 of FIG. 2 (Part 2).

FIG. 18 illustrates one phase of a manufacturing process flow and is one example of a schematic vertical cross-sectional side view taken along line 3-3 of FIG. 2 (Part 3).

FIG. 19 illustrates one phase of a manufacturing process flow and is one example of a schematic vertical cross-sectional side view taken along line 3-3 of FIG. 2 (Part 4).

FIG. 20 illustrates one phase of a manufacturing process flow and is one example of a schematic vertical cross-sectional side view taken along line 3-3 of FIG. 2 (Part 5).

FIG. 21 illustrates one phase of a manufacturing process flow and is one example of a schematic vertical cross-sectional side view taken along line 3-3 of FIG. 2 (Part 6).

FIG. 22A illustrates one phase of a manufacturing process flow and is one example of a plan view of a bit line contact region (Part 1)

FIG. 22B illustrates one phase of a manufacturing process flow and is one example of a plan view of a bit line contact region (Part 2)

FIG. 22C illustrates one phase of a manufacturing process flow and is one example of a plan view of a bit line contact region (Part 3)

FIG. 23A illustrates one phase of a manufacturing process flow and is one example of a plan view of a bit line contact region (Part 1)

FIG. 23B illustrates one phase of a manufacturing process flow and is one example of a plan view of a bit line contact region (Part 2)

FIG. 23C illustrates one phase of a manufacturing process flow and is one example of a plan view of a bit line contact region (Part 3)

FIG. 23D illustrates one phase of a manufacturing process flow and is one example of a plan view of a bit line contact region (Part 4)

FIG. 23E illustrates one phase of a manufacturing process flow and is one example of a plan view of a bit line contact region (Part 5)

FIG. 23F illustrates one phase of a manufacturing process flow and is one example of a plan view of a bit line contact region (Part 6)

FIG. 24 illustrates one phase of a manufacturing process flow of a fourth embodiment and is one example of a schematic vertical cross-sectional side view taken along line 3-3 of FIG. 2 (Part 1).

FIG. 25 illustrates one phase of a manufacturing process flow and is one example of a schematic vertical cross-sectional side view taken along line 3-3 of FIG. 2 (Part 2).

FIG. 26 illustrates one phase of a manufacturing process flow and is one example of a schematic vertical cross-sectional side view taken along line 3-3 of FIG. 2 (Part 3).

FIG. 27 illustrates one phase of a manufacturing process flow and is one example of a schematic vertical cross-sectional side view taken along line 3-3 of FIG. 2 (Part 4).

FIG. 28 illustrates one phase of a manufacturing process flow and is one example of a schematic vertical cross-sectional side view taken along line 3-3 of FIG. 2 (Part 5).

FIG. 29 illustrates one phase of a manufacturing process flow and is one example of a schematic vertical cross-sectional side view taken along line 3-3 of FIG. 2 (Part 6).

FIG. 30 illustrates one phase of a manufacturing process flow of a fifth embodiment and is one example of a schematic vertical cross-sectional side view taken along line 3-3 of FIG. 2.

FIG. 31 illustrates one phase of a manufacturing process flow and is one example of a schematic vertical cross-sectional side view taken along line 3-3 of FIG. 2 (Part 1).

FIG. 32 illustrates one phase of a manufacturing process flow and is one example of a schematic vertical cross-sectional side view taken along line 3-3 of FIG. 2 (Part 2).

FIG. 33 illustrates one phase of a manufacturing process flow and is one example of a schematic vertical cross-sectional side view taken along line 3-3 of FIG. 2 (Part 3)

FIG. 34A illustrates one phase of a manufacturing process flow of a sixth embodiment and is one example of a schematic vertical cross-sectional side view taken along line 3-3 of FIG. 2.

FIG. 34B illustrates one phase of a manufacturing process flow and is one example of a schematic vertical cross-sectional side view taken along line 34B-34B of FIG. 2.

FIG. 35 illustrates one phase of a manufacturing process flow of a seventh embodiment and is one example of a schematic vertical cross-sectional side view taken along line 3-3 of FIG. 2.

### DETAILED DESCRIPTION

In one embodiment, a semiconductor storage device includes a semiconductor substrate; a first layer memory cell having the semiconductor substrate serving as a channel layer; a semiconductor layer provided along the first layer memory cell via an insulating film; and a second layer memory cell having the semiconductor layer serving as a channel layer. The semiconductor layer of the second memory cell layer comprises a polycrystalline silicon film including a single crystal region.

### First Embodiment

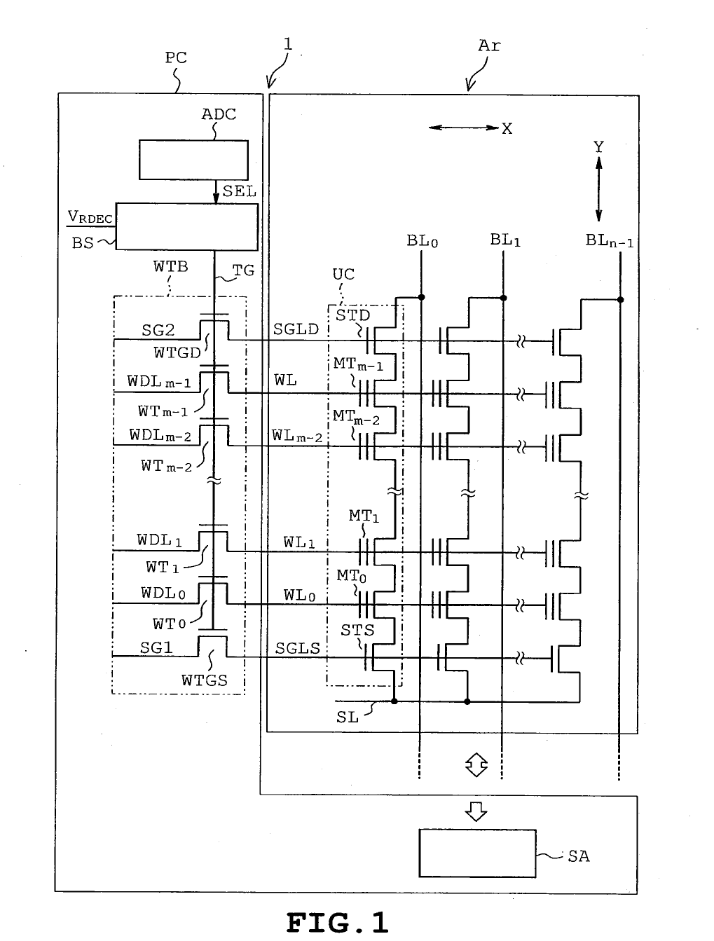

A first embodiment is described hereinafter based on an application of evaluation element for a NAND flash memory device with references to FIGS. 1 to 10. The drawings are schematic and are not necessarily consistent with the actual measurements of the features such as the correlation of thickness to planar dimensions and the ratio of thicknesses of different layers. Further, directional terms such as up, down, left, and right are used in a relative context with an assumption that the worked surface, on which circuitry is formed of the later described semiconductor substrate faces up. Thus, the directional terms do not necessarily correspond to the directions based on gravitational acceleration.

FIG. 1 is one schematic example of a diagram illustrating an electrical configuration of a NAND flash memory device. As shown in FIG. 1, NAND flash memory device 1 is provided with memory cell array Ar, peripheral circuit region PC and input/output interface circuitry not shown. Memory cell array Ar is configured by multiplicity of memory cells arranged in a matrix. Peripheral circuit PC is configured to read/program/erase each of the memory cells in memory cell array Ar.

Memory cell array Ar is provided in a memory cell region. In the present embodiment, memory cell array Ar is structured by a stack of first layer MM1 and second layer MM2. FIG. 1 illustrates the electrical configuration of first layer MM1 in memory cell array Ar but does not illustrate the electrical configuration of second layer MM2. Memory cell array Ar employs the so-called memory cell array structure and the electrical configuration of second layer MM2 is substantially identical to the electrical configuration of first layer MM1. Thus, a description is given hereinafter on the electrical configuration of first layer MM1 and a description on the electrical configuration of second layer MM2 will not be given. The present embodiment discloses an example in which the stack of memory cell arrays Ar has 2 layers but the same is applicable to a structure having 3 or more layers.

Memory cell array Ar includes multiplicity of cell units UC. Cell unit UC has 2^{k} number (for example 32(=m)) of series connected memory cell transistors MT₀ . . . MTₘ₋₁ situated between a couple of select gate transistors STD and STS. Select gate transistors STD are connected to bit line BL₀ . . . BLₙ₋₁, whereas Select gate transistors STS are connected to source line SL. Dummy cells may be series connected between the two Select gate transistors Trs1 and Trs2. Gate electrodes MG of memory cell transistors Trm located in cell units UC aligned in the X direction are electrically connected by word line WL.

A block includes n number of cell units UC aligned in the X direction (row direction: the left and right direction as viewed in FIG. 1). The X direction is also referred to as a first direction. Memory cell array Ar includes multiple blocks aligned in the Y direction (column direction: the up and down direction in FIG. 1). The Y direction is also referred to as a second direction. FIG. 1 only shows one block for simplicity.

The memory cell region is surrounded by the peripheral circuit region and peripheral circuit PC is located in the periphery of memory cell array Ar. Peripheral circuit PC includes address decoder ADC, sense amplifier SA, booster circuit BS provided with a charge pump circuit, and transfer transistor WTB. Address decoder ADC is electrically connected to transfer transistor WTB through booster circuit BS.

Address decoder ADC selects a given block based on an incoming address signal provided from an external component and sends block selection signal SEL to step-up circuit BS. Booster circuit BS, when given a selection signal SEL from block B, steps up drive voltage VRDEC received from a component outside address decoder ADC and supplies the stepped up drive voltage VAnzc, being stepped up to a predetermined level, to each of transfer transistors WTGD, WTGS, and WT₀ to WTₘ₋₁ by way of transfer gate line TG.

Transfer transistor WTB is provided with transfer gate transistors WTGD being associated with Select gate transistors STD, transfer gate transistors WTGS being associated with Select gate transistors STS, word line transfer transistors WT₀ to WTₘ₋₁, being associated with each of memory cell transistors MT₀ to MTₘ₋₁, and the like. Transfer transistor WTB is given in each block B.

Transfer gate transistor WTGD is configured such that either of the drain and source is connected to select gate driver line SG2, and the remaining other is connected to select gate line SGLD. Transfer gate transistor WTGS is configured such that either of the drain and source is connected to select gate driver line SG1, and the remaining other is connected to select gate line SGLS. Each of word line transfer gate transistors WT₀ to WTₘ₋₁ is configured such that either of the drain and source is uniquely connected to word line drive signal lines WDL₀ to WDLₘ₋₁ respectively, and the remaining other is uniquely connected to word lines WL₀ to WLₘ₋₁ provided in memory cell array Ar (memory cell region M).

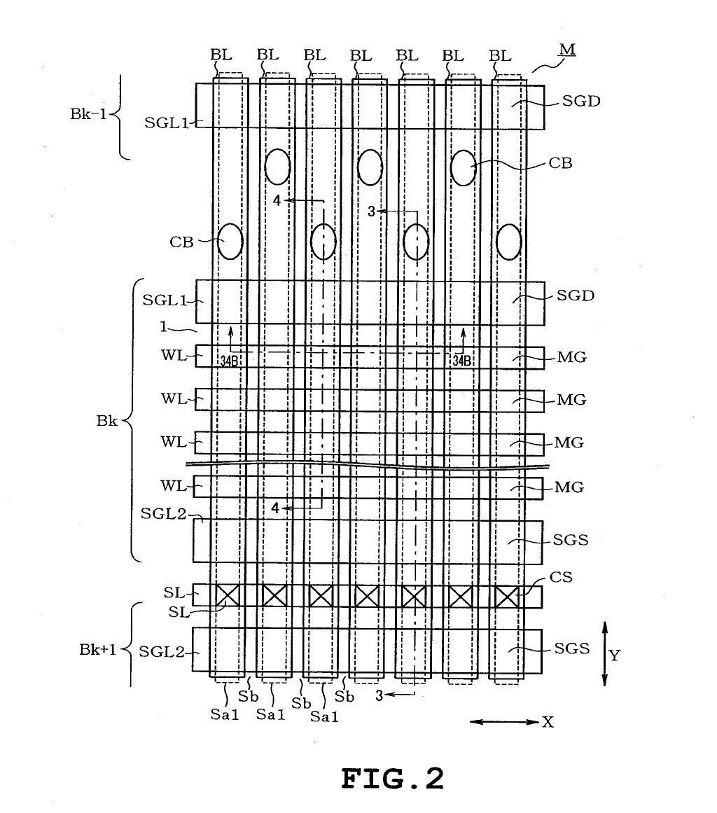

Gate electrodes SG of Select gate transistors STD of cell units UC aligned in the X direction are electrically connected by common select gate line SGLD. Similarly, gate electrodes SG of Select gate transistors STS of the cell units UC aligned in the X direction are electrically connected by common select gate line SGLS. The sources of Select gate transistors STS are connected to common source line SL. Select gate transistors STD and STS are each referred to as select gate transistor Trs in the descriptions for FIG. 2 and beyond.

Gate electrodes MG of memory cell transistors MT₀ to MTₘ₋₁, of the cell units UC aligned in the X direction are electrically connected by common word lines WL₀ to WLₘ₋₁ respectively. Memory cell transistors MT₀ to MTₘ₋₁ are each referred to as memory cell transistor Trm in the descriptions for FIG. 2 and beyond.

Gate electrodes of transfer transistors WTGD, WTGS, and WT₀ to WTₘ₋₁ are interconnected by common transfer gate line TG, which is turn, connected to an output terminal of booster circuit BS for supplying stepped up voltage. Sense amplifier SA is connected to bit lines BL₀ to BLₙ₋₁ and a latch circuit configured to temporarily store the data which has been read during data readout.

FIG. 2 is one example of a plan view schematically illustrating the layout of some of the blocks in first layer MM1 in the memory cell region. The layout of the blocks in second layer MM2 are substantially identical to the layout of the blocks of first layer MM1.

Each of blocks B aligned in the Y direction shares bit line contact CB region or source-line contact CS region with adjacent blocks B on both sides thereof. Thus, as illustrated in FIG. 2, select gate line SGL1 of block Bk is disposed so as to face select gate line SGL1 of block Bk−1 over the region for forming bit line contact CB. Further, select gate line SGL2 of block Bk is disposed so as to face select gate line SGL2 of block Bk+1 over the region for forming source line contact CB.

Silicon substrate 1 which is used for example as a semiconductor substrate is provided with element isolation regions Sb taking an STI (shallow trench isolation) structure running along the Y direction as viewed in FIG. 2. Element isolation regions Sb may be provided by filling trenches formed into the surface layer silicon substrate 1 with an insulating film. The surface layer portion of silicon substrate 1 is isolated in the X direction over a predetermined spacing by element isolation regions Sb to form element region Sa1 of each cell unit UC1 in first layer MM1.

Thus, element regions Sa1 extending along the Y direction are isolated from one another in the X direction. Element regions Sa1 are formed in equal X-direction width and equal X-direction spacing from one another. Gate electrodes of memory cell transistors Trm and select gate transistors Trs are formed above element regions Sa1. Word lines WL and select gate lines SGL1 and SGL2 extend in the X direction.

Bit line contacts CB are disposed in the region between select gate lines SGL. Bit line contacts CB are provided so as to be associated with each of element regions Sa1 and are displaced in the Y direction from the bit line contacts CB disposed in the adjacent element regions Sa1. Thus, bit line contacts CB are disposed alternately in the X direction over two rows so as to be in a zigzag layout. A wide space is provided between select gate lines SGL1 because two bit line contacts CB are aligned in the Y direction. Three or more bit line contacts CB may be aligned in the region between select gate lines SGL1.

Further, source line contacts CS are disposed in the region between select gate lines SGL2. Source line contacts CS are linked in the X direction so as to contact element region Sa1 of each of the adjacent cell units UC1 at once.

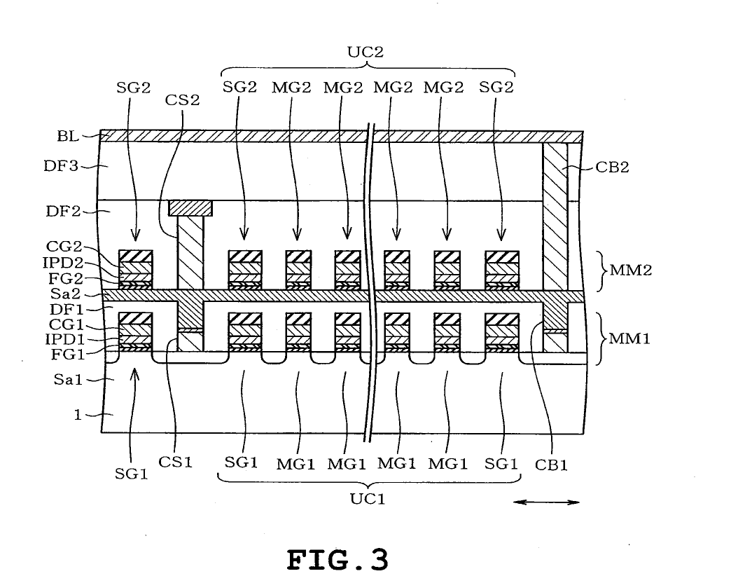

The above describes the structures of first layer MM1 of memory cell array Ar including cell unit UC1. In the present embodiment, second layer MM2 is stacked above first layer MM1 via an interlayer insulating film as illustrated in FIG. 3. Source lines SL and bit lines BL are disposed above the stacked memory cell array structure formed of first layer MM1 and second layer MM2.

As illustrated in FIG. 2, bit lines BL extend in the Y direction as viewed in FIG. 2 along element region Sa1 and are spaced from one another in the X direction. Bit lines BL are formed in equal X-direction width and are spaced from one another in equal X-direction spacing. Source lines SL extend over source line contacts CS of multiple cell units UC1 and are disposed along the X direction.

Referring next to FIG. 3, a brief description will be given on the structure of cell unit UC of the stacked memory cell array Ar with reference to FIG. 3. In FIG. 3, the elements of first layer MM1 is suffixed by “1” and the elements of second layer MM2 are suffixed by “2”.

Cell unit UC1 of first layer MM1 is provided above element region Sa1 of silicon substrate 1. Select gate electrode SG1 is disposed at both ends of cell unit UC1 and memory cell gate electrodes MG1 are disposed between select gate electrodes SG1. Gate electrodes MG1 and SG1 are disposed above gate insulating film 2 formed above silicon substrate 1. Bit line contact CB1 is disposed between one opposing pair of select gate electrodes SG1 of adjacent cell units UC1 and source line contact CS1 is disposed between the other opposing pair of select gate electrodes SG1 of adjacent cell units UC1.

Memory gate electrode MG1 and select gate electrode SG1 are formed by stacking charge storing layer FG1, interelectrode insulating film IPD1 and control electrode CG1 one after another. An insulating film is provided above the upper surface of control electrode CG1. Interelectrode insulating film DF1 is disposed so as to cover memory gate electrode MG1 and select gate electrode SG1. As later described, interlayer insulating film DF1 includes an insulating film for forming air gaps between memory gate electrodes MG1. The upper surface of interlayer insulating film DF1 is planarized.

Element region Sa2 of second layer MM2 is provided above the upper surface of interlayer insulating film DF1. Element regions Sa2 serves as a channel layer and is formed of a polycrystalline silicon film. Element region Sa2 is substantially identical in shape such as width and spacing as element region Sa1 of first layer MM1. The polycrystalline silicon film provided in element region Sa2 is formed for example by crystallizing an amorphous silicon film.

Cell unit UC2 of second layer MM2 is disposed above element region Sa2. As was the case in first layer MM1, select gate electrode SG2 is provided at both ends of cell unit UC2 of second layer MM2 and memory gate electrodes MG2 are disposed between select gate electrodes SG2. Gate electrodes MG2 and SG2 are disposed above gate insulating film 2 formed above gate insulating film formed above polycrystalline silicon film of element region Sa2. Bit line contact CB2 is disposed between one opposing pair of select gate electrodes SG2 of adjacent cell units UC2 and source line contact CS2 is disposed between the other opposing pair of select gate electrodes SG2 of adjacent cell units UC2.

Memory gate electrode MG2 and select gate electrode SG2 are formed by stacking charge storing layer FG2, interelectrode insulating film IPD2 and control electrode CG2 one after another. An insulating film is provided above the upper surface of control electrode CG2. Interelectrode insulating film DF2 is disposed so as to cover memory gate electrode MG2 and select gate electrode SG2. As later described, interlayer insulating film DF2 includes an insulating film for forming air gaps between memory gate electrodes MG2. The upper surface of interlayer insulating film DF2 is planarized.

Source line SL is embedded into the upper surface of interlayer insulating film DF2. Interlayer insulating film DF3 is disposed above the upper surface of interlayer insulating film DF2. Bit line BL is embedded into the upper surface of interlayer insulating film DF3. Source line contact CS2 extends through interlayer insulating film DF2 and electrically connects source line contact CS1 with source line SL. Bit line contact CB2 extends through interlayer insulating film DF2 and DF3 and electrically connects bit line contact CB1 with bit line BL.

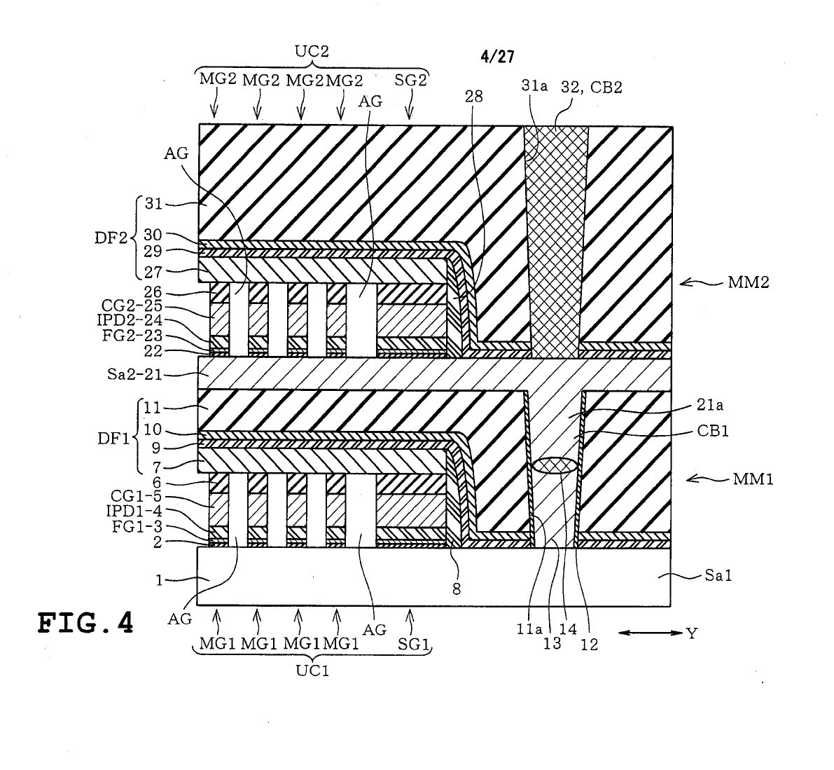

In the above described structure, bit line contact CB1 and source line contact CS1 of first layer MM1 are each provided with a silicide layer in a mid portion thereof which is formed during the formation of the polycrystalline silicon film of element region Sa2. This structure will be described in detail hereinafter with reference to FIG. 4. FIG. 4 is a vertical cross-sectional side view of the portion taken along line 4-4 of FIG. 2 and illustrates substantially the same structures as FIG. 3 with a focus placed on a portion where parts of cell units UC1 and UC2 as well as bit line contact CB are formed.

A P-type single crystal silicon may be used for example as silicon substrate 1 serving as a semiconductor substrate in FIG. 4. The upper surface of silicon substrate 1 is provided with element isolation regions Sb extending in the Y direction and being spaced from one another in the X direction. Element isolation region Sb is formed by filling an element isolation trench with an element isolation insulating film. The surface portion of silicon substrate 1 is isolated in the X direction by element isolation regions Sb taking an STI structure to form element isolation regions Sa1 extending in the Y direction.

Cell unit UC1 of first layer MM1 is disposed in element region Sa1 of silicon substrate 1. Memory gate electrodes MG1 are formed in the upper surface of element region Sa1 via gate insulating film 2. Memory gate electrode MG1 is configured by stacking charge storing layer FG1, interelectrode film IPD1, and control electrode CG1 one after another above the upper surface of gate insulating film 2.

Gate insulating film 2 is formed in element isolation region Sa1 of silicon substrate 1 and is formed of a silicon oxide film for example. Charge storing layer FG1 may be provided as conductive film 3 provided with a polycrystalline silicon film and a charge trap film provided above the polycrystalline silicon film. The polycrystalline silicon film may be doped with phosphorous or boron for example. The charge trap film may be formed of a silicon nitride film (SiN) or a hafnium oxide film (HfO) for example. The charge trap film may be provided in a flat cell structure which is provided with a thin polycrystalline silicon film.

Interelectrode insulating film IPD1 is provided with high dielectric constant film 4 such as a metal oxide film containing materials such as a nitride (N), hafnium (Hf), and aluminum (Al). High dielectric constant film 4 may be replaced by a silicon oxide film (SiO₂) or a composite film in which a silicon oxide film is stacked above high dielectric constant film 4.

Control electrode CG1 is configured by conductive film 5 and serves as word line WL of memory cell transistor Trm. A metal film such as tungsten (W), a polycrystalline silicon film doped with impurities such as phosphorous, a silicide film, or a composite of film formed of a stack of the forgoing films may be used as conductive film 5. Insulating film 6 formed of a silicon oxide film or the like is disposed above conductive film 5.

Memory gate electrodes MG1 forming cell unit UC1 are aligned in the Y direction. Gate electrodes SG1 of select transistors Trs1 and Trs2 are disposed adjacent to memory gate electrode MG1 at both sides of cell unit UC1. FIG. 4 illustrates select gate electrode SG1 in one side of cell unit UC1 where bit line contact CB1 is formed.

The stack structures of select gate electrodes SG1 are identical to the stack structure of memory gate electrode MG1 and are configured by charge storing layer FG1, interelectrode insulating film IPD1, and control electrode CG1 stacked one after another. Select gate electrode SG1 is an ordinary transistor and does not require a floating charge storing layer FG1 as in memory gate electrode MG1. Thus, it is possible to electrically short charge storing layer FG1 and control electrode CG1 by placing the two in contact through an opening provided in interelectrode insulating film IPD1. Further, in a flat cell structure in which the thin floating gate electrode FG1 cannot be electrically shorted, the floating state may be maintained.

Interlayer insulating film DF1 is provided so as to cover the upper surfaces of memory gate electrode MG1 and select gate electrode SG1 structured as described above and fill the contact regions. More specifically, interlayer insulating film DF1 is a stack of insulating films. Insulating film 7 for forming gaps is formed so as to extend across and over memory gate electrodes MG1 and select gate electrode SG1 and closes the upper portions of the recessed regions located between gate electrodes MG1 and between gate electrodes MG1 and SG1. Thus, the recessed regions located between gate electrodes MG1 and between gate electrodes MG1 and SG1 are formed into gaps which serve as air gaps AG that isolate the elements using vacuum or air as a dielectric. Spacers 8 are formed along the sidewalls of select gate electrodes SG1 in the contact region.

Silicon oxide film 9 and silicon nitride film 10 serving as liner films are provided so as to cover insulating film 7 and spacers 8. Interlayer insulating film 11 is provided above silicon nitride film 10 so as to fill the contact region. The upper surface of interlayer insulating film 11 is planarized. Interlayer insulating film DF1 is a stack of insulating film 7, spacers 8, silicon oxide film 9, silicon nitride film 10, and interlayer insulating film 11 as described above.

In the contact region located between select gate electrodes SG1 (only one is illustrated in FIG. 4), contact plug CB1 is disposed to connect to bit line BL. Contact plug CB1 is provided in contact hole 11a, extending through interlayer insulating film 11, silicon nitride film 10, and silicon oxide film 9 from the upper surface of interlayer insulating film 11, via silicon oxide film 12. Contact plug CB1 is provided so as to extend from the upper surface portion of interlayer insulating film 11 to the upper surface of silicon substrate 11. Contact plug CB1 is provided with lower contact 13, formed by filling the lower portion of contact hole 11a with polycrystalline silicon film, and silicide layer 14 disposed above the upper surface of lower contact 13. Upper contact 21a formed of polycrystalline silicon film is disposed above silicide layer 14 of contact hole 11a. Silicide layer 14 is a nickel silicide film for example.

Next a description will be given on the structures of cell unit UC2 of second layer MM2 provided above first layer MM1. Polycrystalline silicon film 21a serving as element isolation regions Sa2 is provided above interlayer insulating film 11. Polycrystalline silicon film 21 is substantially identical in shape such as width and spacing as element region Sa1 of silicon substrate 1. Polycrystalline silicon film 21 is formed as the result of transformation through the later described process flow and exhibits greater mobility in terms of electrical properties as compared to a film formed originally as polycrystalline silicon film 21. Polycrystalline silicon film 21 is formed in one with upper contact 21a of contact plug CB1 of first layer MM1.

Cell unit UC2 of second layer MM2 is disposed above polycrystalline silicon film 21. Memory gate electrodes MG2 are formed in the upper surface of element region Sa2 via gate insulating film 22. Memory gate electrode MG2 is configured by stacking charge storing layer FG2, interelectrode film IPD2, and control electrode CG2 one after another above the upper surface of gate insulating film 22.

Gate insulating film 22 is formed above polycrystalline silicon film 21 and is formed of a silicon oxide film for example. Charge storing layer FG2 may be provided as conductive film 23 similar to conductive film 3. Interelectrode insulating film IPD2 is provided with high dielectric constant film 24 similar to high dielectric constant film 4. Control electrode CG2 is configured by conductive film 25 similar to conductive film 5 and serves as word line WL of memory cell transistor Trm. Insulating film 26 formed of a silicon oxide film or the like is disposed above conductive film 25.

Memory gate electrodes MG2 forming cell unit UC2 are aligned in the Y direction. Gate electrodes SG2 of select transistors Trs1 and Trs2 are disposed adjacent to memory gate electrode MG2 at both sides of cell unit UC2.

The stack structures of select gate electrodes SG2 are identical to the stack structure of memory gate electrode MG2 and are configured by charge storing layer FG2, interelectrode insulating film IPD2, and control electrode CG2 stacked one after another.

Interlayer insulating film DF2 is provided so as to cover the upper surface of memory gate electrode MG2 and select gate electrode SG2 structured as described above and fill the contact regions. Interlayer insulating film DF2 is a stack of insulating film 27 for forming gaps, spacers 28, silicon oxide film 29, silicon nitride film 30, and interlayer insulating film 31.

In the contact region located between select gate electrodes SG2, contact plug CB2 is disposed to connect to bit line BL. Contact plug CB2 is provided in contact hole 31a, extending through interlayer insulating film 31, silicon nitride film 30, and silicon oxide film 29 from the upper surface of interlayer insulating film 31 so to contact the upper surface of polycrystalline silicon film 21. Contact plug CB2 is formed by filling contact hole 31a with a metal film 32 such as tungsten (W). Thus, contact plug CB2 and contact plug CB1 are connected over polycrystalline silicon film 21.

Interlayer insulating films DF3 and DF4, as well as source line SL and bit line BL, and the like are not illustrated in the structure of FIG. 4.

Polycrystalline silicon film 21 being crystallized after film formation is provided as element region Sa2 of second layer MM2 disposed above first layer MM1 as described above. Thus, it is possible to improve mobility as compared to a polycrystalline silicon film being formed originally as a polycrystalline silicon film and thereby improve the properties of memory cell transistor Trm of second layer MM2.

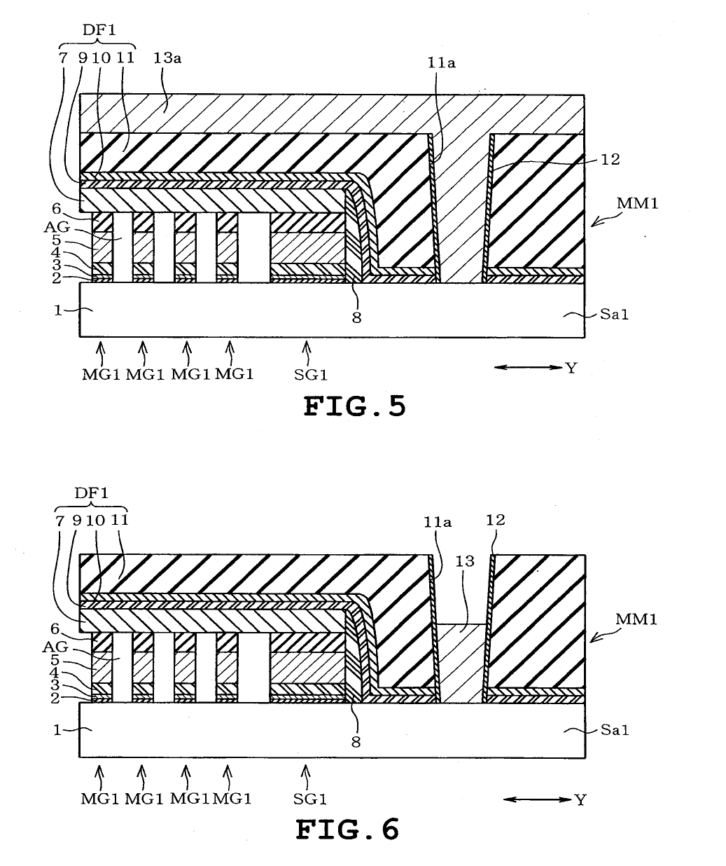

Next, a description will be given on a manufacturing process flow of the above described structure with reference FIGS. 5 to 10. The description given in the present embodiment will focus on the process steps for forming polycrystalline silicon film 21. Process steps for forming memory cell transistors in the memory cell region, etc. will be described briefly. Known steps may be added to/removed from the process steps. The process steps may be rearranged if practicable. The following description is based on the process steps for forming polycrystalline silicon film 21 in bit line contact CB side; however, the following process steps may be applied to polycrystalline silicon film 21 in source line contact CS side.

First, a brief description will be given on the process steps for obtaining the structure illustrated in FIG. 5. Gate insulating film 2 and conductive film 3 such as a polycrystalline silicon is formed above silicon substrate 1. Then, processing for forming element isolation regions Sb is carried out by lithography to form element regions Sa1 in silicon substrate 1. High dielectric constant film 4, conductive film 5, and insulating film 6 are formed thereafter.

Gate insulating film 2 is formed for example by thermally oxidizing a silicon oxide film. Conductive film 3 serving as charge storing layer FG1 is formed by CVD as a polycrystalline silicon film doped with phosphorous or boron. A charge trap film formed of a silicon nitride film (SiN) or hafnium oxide (HfO) may be further formed above the polycrystalline silicon film.

High dielectric constant film 4 may be formed as a metal oxide film containing a nitride (N), hafnium (Hf), aluminum (Al), or the like. High dielectric constant film 4 may also be formed of a silicon oxide film (SiO₂). Alternatively, a composite film may be used which is a stack of the above described metal oxide film and a silicon oxide film. Conductive film 5 may be formed of a polycrystalline silicon film doped with impurities such as phosphorous. Metal film such as tungsten (W), a silicide film, or a composite formed of a stack of the foregoing films may be stacked above the polycrystalline silicon film.

Then, gate processing for forming memory gate electrode MG1 and select gate electrode SG1 are carried out by lithography and RIE. Thereafter, insulating film 7 is formed by forming a silicon oxide film or the like under conditions providing poor gap fill capabilities to form air gaps AG between gate electrodes MG of the memory cells. Then, an insulating film such as a silicon oxide film is formed by CVD and is etched back to form spacers 8 along the sidewalls of select gate electrodes SG1. Then, silicon oxide film 9 and silicon nitride film 10 serving as liner films are formed, followed by formation of interlayer insulating film 11 to obtain a planar upper surface.

Contact hole 11a is formed into interlayer insulating film 11 located in the contact region located between select gate electrodes SG1. Silicon oxide film 12 is formed along the sidewalls of contact hole 11a. Then, polycrystalline silicon film 13a is formed into contact hole 11a and along interlayer insulating film 11. Polycrystalline silicon film 13a may be formed as an amorphous silicon film. This is the state illustrated in FIG. 5.

Referring now to FIG. 6, the stacked polycrystalline silicon film 13a is etched back to remove the upper surface portion of polycrystalline silicon film 13a above interlayer insulating film 11 and a portion of polycrystalline silicon film 13a inside contact hole 11a. As a result, amorphous silicon film 13a remains from the bottom surface to the mid portion within contact hole 11a and serves as lower contact 13. It is possible to reduce the contact resistance of polycrystalline silicon film 13a and silicon substrate 1 by doping impurities such as boron into polycrystalline silicon film 13a.

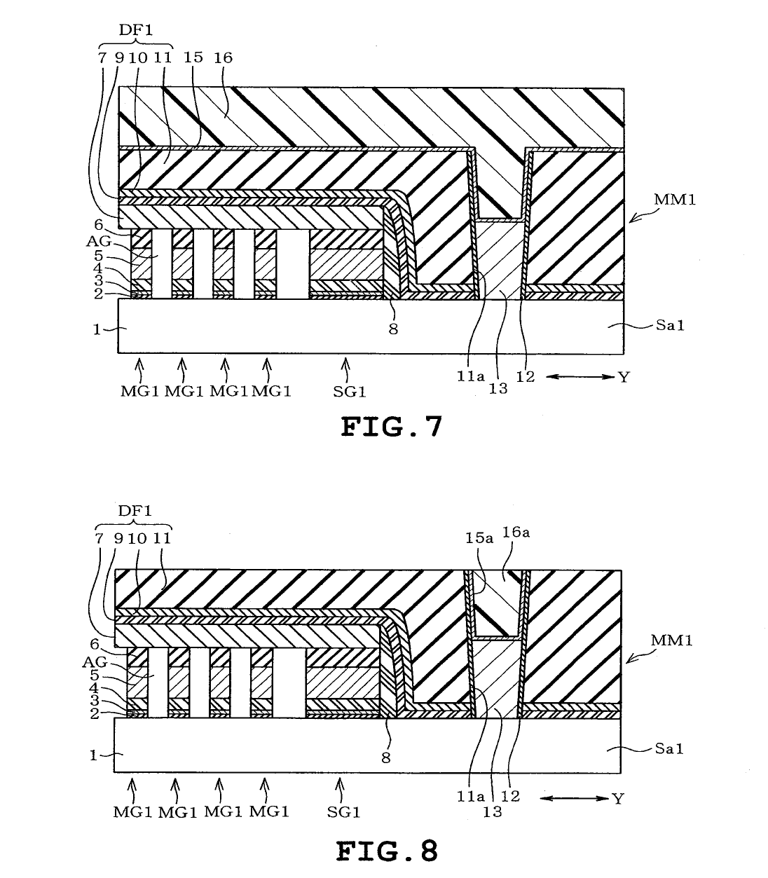

Then, as illustrated in FIG. 7, metal film 15 is formed along the upper surface of polycrystalline silicon film 13 exposed along interlayer insulating film 11 and along the sidewalls of and in the interior of contact hole 11a. Metal film 15 comprises metal species, a typical example of which is nickel (Ni), which can be crystallized using MiLC (metal induced lateral crystallization). Next, resist film 16 is coated across the entire surface of metal film 15 to fill contact hole 11a and obtain a planar upper surface.

Next, as illustrated in FIG. 8, resist film 16 and metal film 15 above interelectrode insulating film 11 are removed by etch back using RIE or the like. Under such state, metal film remains along the side surfaces and along the surface of polycrystalline silicon film 13 and resist film 16a remains so as to bury these structures.

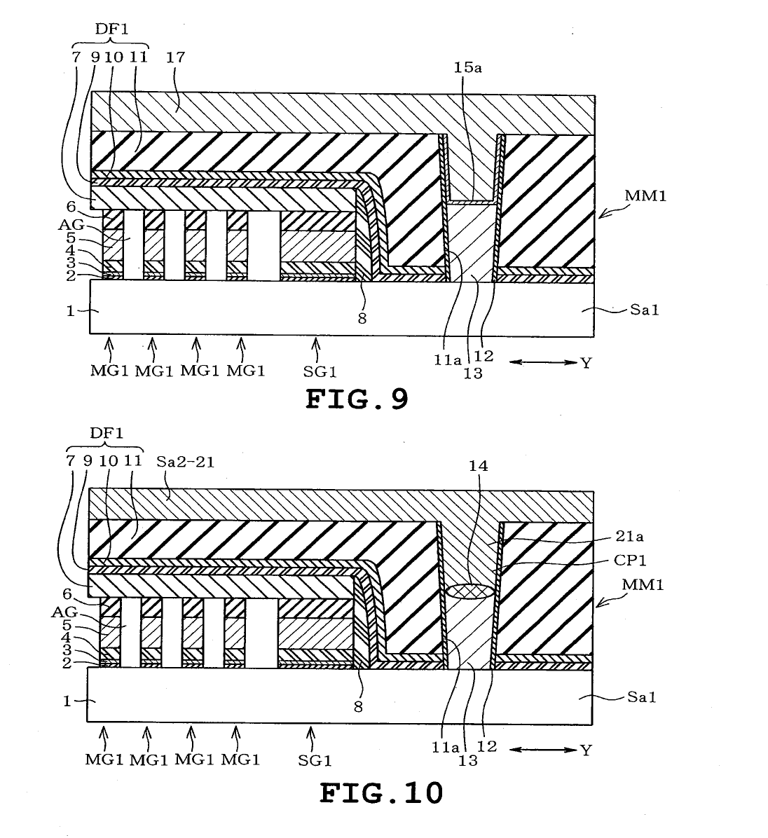

Then, as illustrated in FIG. 9, amorphous silicon film 17 is formed along interlayer insulating film 11 and so as to fill contact hole 11a. Amorphous silicon film 17 is formed so as to serve as element region Sa2 of second layer MM2 and is preferably doped with impurities such as boron to reduce the resistance. Thus, amorphous silicon film 17 is provided so as to contact metal film 15a inside contact hole 11a.

Then, as illustrated in FIG. 10, thermal treatment is carried out to crystallize amorphous silicon film 17. In this example, the application of heat forms silicide layer 14 by the reaction of amorphous silicon film 17 with metal film 15a and the crystallization of amorphous silicon film 17 progresses with silicide layer 14 serving as the seed. As a result, amorphous silicon film 17, formed along the upper surface of interlayer insulating film 11 from the interior of contact hole 11a, crystallizes in the lateral direction. Thus, amorphous silicon film 17 is generally transformed into polycrystalline silicon film 21 as illustrated in FIG. 4. Metal film 15a formed along the sidewalls of contact hole 11a is silicided by being taken into the amorphous silicon film 17 during the thermal treatment.

Then, as illustrated in FIG. 4, polycrystalline silicon film 21 is processed into element region Sa2 and memory gate electrode MG2 and select gate electrode SG2 of second layer MM2 and the like are further formed. Then, insulating film 27 for forming air gap AG and serving as interlayer insulating film DF2 is formed and spacers 28 are further formed along the sidewalls of select gate electrodes SG2. Thereafter, silicon oxide film 29 and silicon nitride film 30 serving as liner films are formed, followed by formation of interlayer insulating film 31 to bury the foregoing. Contact hole 31a is formed through interlayer insulating film 31 to form conductive layer 32 serving as contact plug CB2.

The first embodiment described above provides polycrystalline silicon film 21 being crystallized after film formation to serve as element region Sa2 used as a channel layer of second layer MM2. It is thus, possible to increase the mobility of channel layer of second layer MM2 to facilitate flow of channel current and thereby improve device properties as compared to a film formed originally as a polycrystalline silicon film.

Because polycrystalline silicon film 21 is formed through MiLC process, the polycrystalline silicon film contains metal such as nickel.

In the above embodiment, metal species other than nickel (Ni) may be used as metal film 14 as long as MiLC process can be used with such metal.

### Second Embodiment

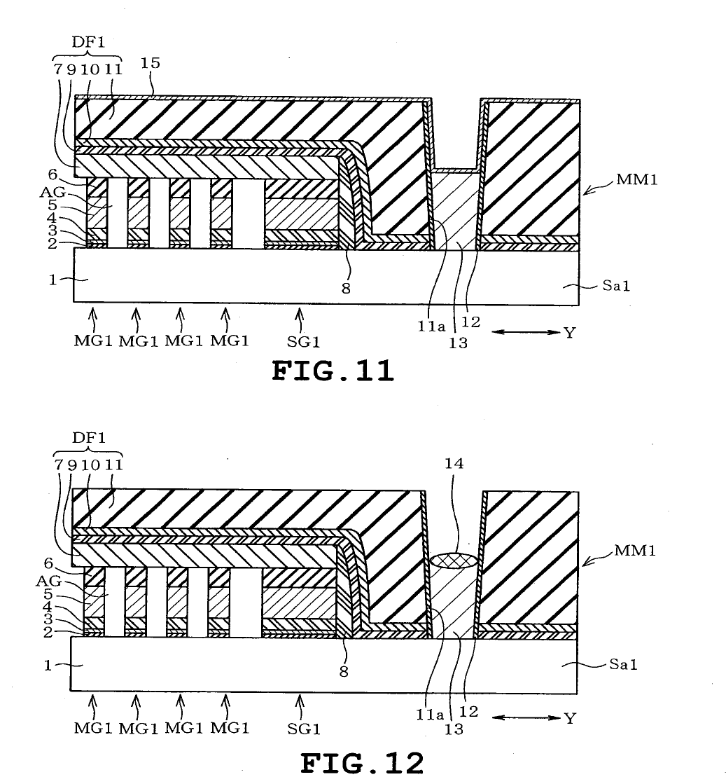

FIGS. 11 to 14 illustrate one example of polycrystalline silicon film 21 of the first embodiment being formed by a different method. This embodiment utilizes the fact that lower contact 13 is formed of a polycrystalline silicon film and provides silicide layer 14, serving as the seed in the MiLC method, prior to the formation of amorphous silicon film 17. Differences in the manufacturing process flow will be given hereinafter.

Starting from the state illustrated in FIG. 6, metal film is formed along interlayer insulating film 11, the sidewall within contact hole 11a, and the upper surface of polycrystalline silicon film 13 exposed in the interior contact hole 11a as illustrated in FIG. 11. Metal film 15 is formed so as to contact the polycrystalline silicon film of lower contact 13 inside contact hole 11a.

Next, as illustrated in FIG. 12, silicide layer 14 is formed by thermally treating the above described structure. The application of heat causes metal film 15 contacting the polycrystalline silicon film of lower contact 13 in the interior of contact hole 11a to be silicided through reaction with silicon. As a result, silicide layer 14 is formed in the upper surface portion of lower contact 13. Metal films 15 located in other portions are removed by a chemical liquid treatment or the like.

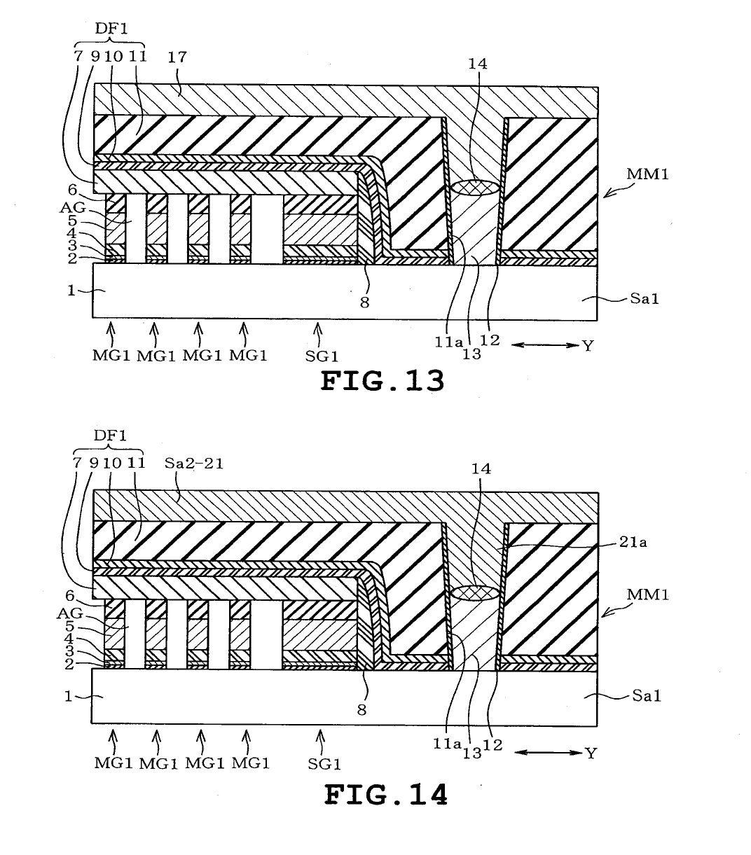

Next, as illustrated in FIG. 13, amorphous silicon film 17 is formed so as to extend along interlayer insulating film 11 and further fill contact hole 11a. In this example, amorphous silicon film 17 is provided so as to contact silicide layer 14 in contact hole 11a.

Referring next to FIG. 14, thermal treatment is performed to crystallize amorphous silicon film 17. In this example, the application of heat progresses the crystallization of amorphous silicon film 17 with silicide layer 14 serving as the seed. As a result, amorphous silicon film 17, formed along the upper surface of interlayer insulating film 11 from the interior of contact hole 11a, crystallizes in the lateral direction. Thus, amorphous silicon film 17 is generally transformed into polycrystalline silicon film 21 as illustrated in FIG. 4.

The present embodiment described above is also capable of obtaining the operation and effect similar to those of the first embodiment.

### Third Embodiment

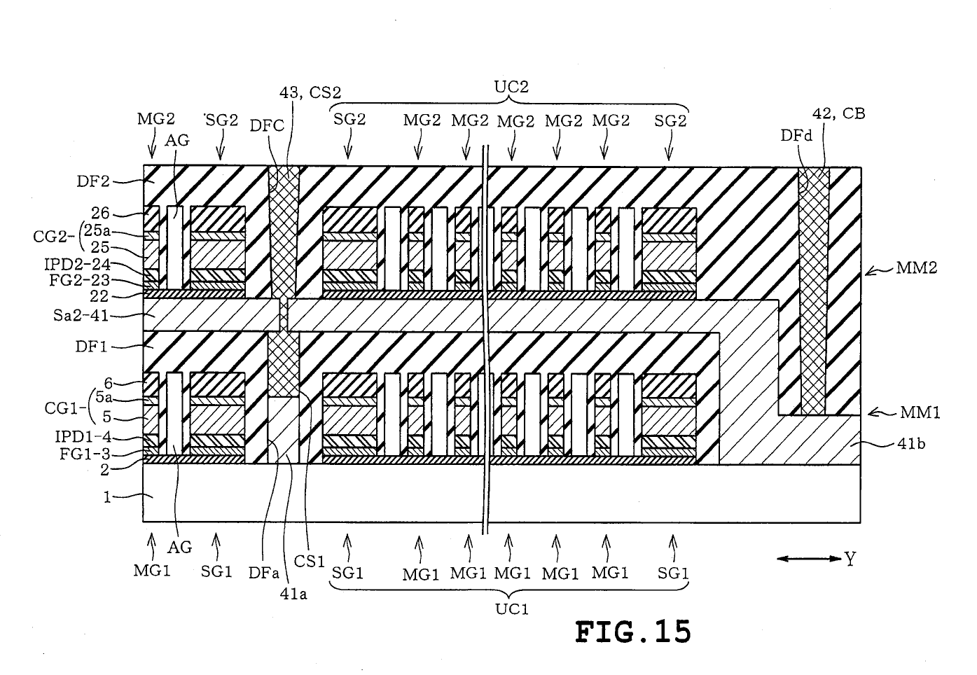

FIGS. 15 to 23 illustrate a third embodiment. In this embodiment, a film is crystallized into a polycrystalline silicon film to serve as element regions Sa2 of second layer MM2 by a method that differs from MiLC described in the first and the second embodiment. A brief description is given hereinafter on the overall structure, followed by a description on the manufacturing process flow of element region Sa2.

In FIG. 15 illustrating the overall structure, element isolation regions Sb are disposed so as to be spaced from one another in the X direction and to extend in the Y direction in the upper surface of silicon substrate 1 serving as a semiconductor substrate. Element isolation region Sb provide element regions Sa1 that extend in the Y direction of the surface layer of silicon substrate 1. Cell unit UC1 of first layer MM1 is provided above element region Sa1 of silicon substrate 1. Memory gate electrodes MG1 are formed in the upper surface of element region Sa1 via gate insulating film 2. Memory gate electrode MG1 is configured by stacking conductive film 3 serving as charge storing layer FG1, high dielectric constant film 4 serving as interelectrode film IPD1, and conductive film 5 serving as control electrode one after another above the upper surface of gate insulating film 2. Conductive film 5 is formed of a polycrystalline silicon film for example and conductive film 5a is formed further above conductive film 5. A silicide film or a metal film may be used as conductive film 5a.

Memory gate electrodes MG1 forming cell unit UC1 are aligned in the Y direction. Gate electrodes SG1 of select transistors Trs1 and Trs2 are disposed adjacent to memory gate electrode MG1 at both sides of cell unit UC1.

The stack structures of select gate electrodes SG1 are identical to the stack structure of memory gate electrode MG1 and is configured by stacking conductive film 3 serving as charge storing layer FG1, high dielectric constant film 4 serving as interelectrode film IPD1, and conductive film 5 serving as control electrode one after another above the upper surface of gate insulating film 2. Conductive film 5 is formed of a polycrystalline silicon film for example and conductive film 5a is formed further above conductive film 5. A silicide film or a metal film may be used as conductive film 5a. Select gate electrode SG1 is an ordinary transistor and does not require a floating charge storing layer FG1 as in memory gate electrode MG1. Thus, it is possible to electrically short charge storing layer FG1 and control electrode CG1 by placing the two in contact through an opening provided in interelectrode insulating film IPD1. Further, in a flat cell structure in which the thin floating gate electrode FG1 cannot be electrically shorted, the floating state may be maintained.

Interlayer insulating film DF1 is provided so as to cover the upper surfaces of memory gate electrode MG1 and select gate electrode SG1 structured as described above and fill the contact regions. More specifically, interlayer insulating film DF1 is a stack of insulating films. Interlayer insulating film DF1 is formed of insulating film for forming gaps, spacers disposed along the sidewalls of select gate electrodes SG1, a silicon oxide film and a silicon nitride film serving as liner films and an interlayer insulating film or the like.

In the contact region located between select gate electrodes SG1, contact plug CS1 is disposed to connect to source line SL. Contact plug CS1 is provided in contact hole DFa, extending through interlayer insulating film DF1 from the upper surface to the lower surface thereof. Contact plug CS1 has a lower portion formed as crystallized silicon portion 42a and an upper portion formed as polycrystalline silicon portion 42b. Further, polycrystalline silicon film 41 has a polycrystalline silicon portion which is not crystallized at the upper portion of contact plug CS1. The polycrystalline silicon portion may be formed to cover a wide range from the upper portion of contact plug CS1 depending upon the state of crystallization. Further, polycrystalline silicon film 41 may be entirely crystallized so as not to provide a polycrystalline silicon portion.

Next a description will be given on the structures of cell unit UC2 of second layer MM2. A crystallized polycrystalline silicon film 41 serving as element isolation regions Sa2 is provided above interlayer insulating film DF1. Polycrystalline silicon film 41 is substantially identical in shape such as width and spacing as element region Sa1 of silicon substrate 1. Polycrystalline silicon film 41 is plunged into first layer MM1 at the contact region and contacts silicon substrate 1 in element region Sa1.

Polycrystalline silicon film 41 is an amorphous silicon film at film formation and is crystallized into a polycrystalline silicon film through the later described process steps. Polycrystalline silicon film 41 exhibits greater mobility in terms of electrical properties as compared to a polycrystalline silicon film formed originally as a polycrystalline silicon film.

Cell unit UC2 of second layer MM2 is disposed above polycrystalline silicon film 41. Memory gate electrodes MG2 are formed in the upper surface of polycrystalline silicon film 41 serving as element region Sa2 via gate insulating film 22. Memory gate electrode MG2 is configured by stacking conductive film 23 serving as charge storing layer FG2, high dielectric constant film 24 serving as interelectrode film IPD2, and conductive film 25 control electrode CG2 one after another above the upper surface of gate insulating film 22. Conductive film 25a is formed of a polycrystalline silicon film for example and conductive film 25a is formed further above conductive film 25. A silicide film or a metal film may be used as conductive film 25a. Insulating film 26 formed of a silicon oxide film or the like is disposed above the upper surface of conductive film 25.

Memory gate electrodes MG2 forming cell unit UC2 are aligned in the Y direction. Gate electrodes SG2 of select transistors Trs1 and Trs2 are disposed adjacent to memory gate electrode MG2 at both sides of cell unit UC2.

The stack structures of select gate electrodes SG2 are identical to the stack structure of memory gate electrode MG2 and are configured by stacking conductive film 23 serving as charge storing layer FG2, high dielectric constant film 24 serving as interelectrode film IPD2, and conductive film 25 control electrode CG2 one after another above the upper surface of gate insulating film 22. Insulating film 26 formed of a silicon oxide film or the like is disposed above the upper surface of conductive film 25.

Interlayer insulating film DF2 is provided so as to cover the upper surface of memory gate electrode MG2 and select gate electrode SG2 structured as described above and fill the contact regions. Interlayer insulating film DF2 is a stack of insulating film for forming gaps, spacers, silicon oxide film, silicon nitride film, and interlayer insulating film.

In the contact regions located between select gate electrodes SG2, contact plug CB shared with first layer MM1 is disposed to connect to bit line BL as well as contact plug CS2 of second layer MM2. Contact plug CB is provided in contact hole DFa, extending from the upper surface of interlayer insulating film DF2 to the upper surface of polycrystalline silicon film 41. Contact plug CB is disposed so as to contact the upper surface of polycrystalline silicon film 41a where polycrystalline silicon film 41 contacts silicon substrate 1. Contact plug CB is formed by filling contact hole DFd with a metal film 42 such as tungsten (W).

Further, Contact plug CS2 is provided in contact hole DFc, extending from the upper surface of interlayer insulating film DF2 to the upper surface of polycrystalline silicon film 41. Contact plug CS2 is disposed so as to contact the upper surface of polycrystalline silicon film 41. Contact plug CS2 is formed by filling contact hole DFc with a metal film 43 such as tungsten (W).

Structures such as interlayer insulating films DF3 and DF4 as well as source line SL and bit line B1 are not illustrated in FIG. 15.

Polycrystalline silicon film 41 being crystallized after film formation is provided as element region Sa2 of second layer MM2 disposed above first layer MM1 as described above. Thus, it is possible to improve mobility and thereby improve the properties of memory cell transistor Trm of second layer MM2.

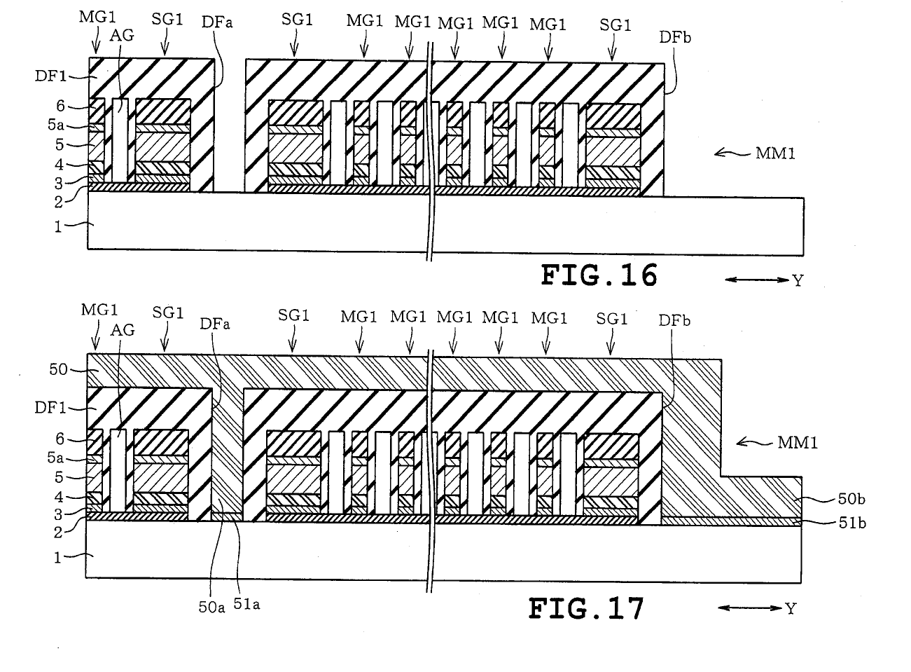

Next, a description will be given on a manufacturing process flow of the above described structure with reference FIGS. 16 to 23. The description given in the present embodiment will focus on the process steps for forming polycrystalline silicon film 41. Process steps for forming memory cell transistors in the memory cell region, etc. will be described briefly. Known steps may be added to/removed from the process steps. The process steps may be rearranged if practicable.

First, a brief description will be given on the process steps for obtaining the structure illustrated in FIG. 16. Gate insulating film 2 and conductive film 3 such as a polycrystalline silicon is formed above silicon substrate 1. Then, processing for forming element isolation regions Sb is carried out by lithography to form element regions Sa1 in silicon substrate 1. High dielectric constant film 4, conductive films 5 and 5a, and insulating film 6 are formed thereafter.

Then, gate processing for forming memory gate electrode MG1 and select gate electrode SG1 are carried out by lithography and RIE. Thereafter, insulating film is formed by forming a silicon oxide film or the like to form air gaps AG between gate electrodes MG of the memory cells. Then, spacers are formed along the sidewalls of select gate electrodes SG1. Then, a silicon oxide film and a silicon nitride film serving as liner films are formed, followed by formation of an interlayer insulating film, thereby providing interlayer insulating film DF1 comprising a composite film of the foregoing films.

Openings DFa and DFb are formed into interlayer insulating film DF1 located in the two contact regions located between select gate electrodes SG1. Opening DFa for source line contact CS1 is formed as a trench having a predetermined width in the Y direction and extending in the X direction. Opening DFb corresponding to bit line contact CB opens up the wide region between select gate electrodes SG1.

In this example, element region Sa1x associated with bit line contact CB is provided so as to be shared by multiple element regions. This is intended to provide a seed layer for performing crystallization using SPE (Solid Phase Epitaxial Growth) which is greater than element region Sa1 of silicon substrate 1.

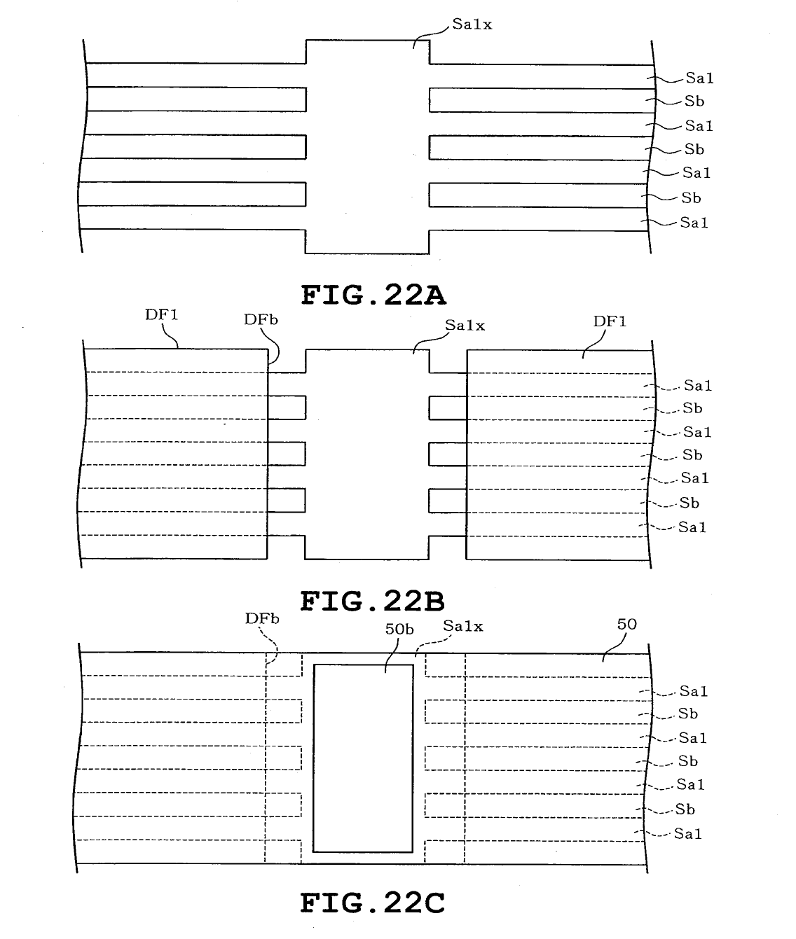

As illustrated in FIG. 22B, opening DFb of interlayer insulating film DF1 provided in FIG. 16 is intended to open element region Sa1x.

Then, as illustrated in FIG. 17, amorphous silicon film 50 is formed above interlayer insulating film DF1. In this example, amorphous silicon film 50 is formed in opening DFa and opening DFb of interelectrode insulating film DF1 as amorphous silicon films 50a and 50b. Opening DFb opens element region Sa1x and thus, amorphous silicon film 50b is formed so as to cover the sidewalls of opening DFb as well as the upper surface of element region Sa1x.

Further, amorphous silicon films 50a and 50b are provided so as to contact silicon substrate 1 at the bottom surface of opening DFa and the bottom surface of opening DFb of interlayer insulating film DF1, respectively. However, thin native oxide films 51a and 51b are interposed at the interface. Native oxide films 51a and 51b may be naturally occurring films or formed in the chemical cleaning process preceding the formation of amorphous silicon film 50.

FIG. 22C illustrates the state of opening DFb when amorphous silicon film 50 is formed above interlayer insulating film DF1. Amorphous silicon film 50 is provided so that amorphous silicon film 50b portion contacts the underlying element isolation regions Sa1x of silicon substrate 1 in opening DFb of interlayer insulating film DF1 via native oxide film 51b.

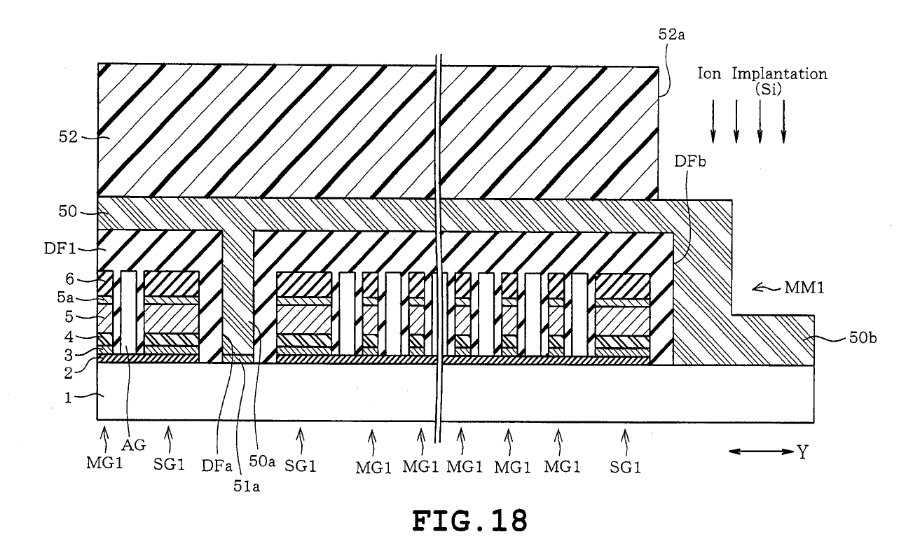

Next, as illustrated in FIG. 18, a photoresist is coated over the entire surface to form resist film 52 and opening 52a is provided therein to open element regions Sa1x portion. Then, ion implantation is carried out using resist film 52 as a mask. In this example, ion implantation is performed by the so-called mixing implantation in which silicon ions are implanted at an energy level to allow the silicon ions to reach the surface layer of silicon substrate 1. As a result, native oxide film 51b on the surface of silicon substrate 1 located in opening 52a dissipates from the surface portion of silicon substrate 1 by diffusing into the bulk interior. Thus, amorphous silicon film 50b of amorphous silicon film 50 located in element regions Sa1x portion is placed in direct contact with silicon substrate 1. Resist film 52 is removed thereafter.

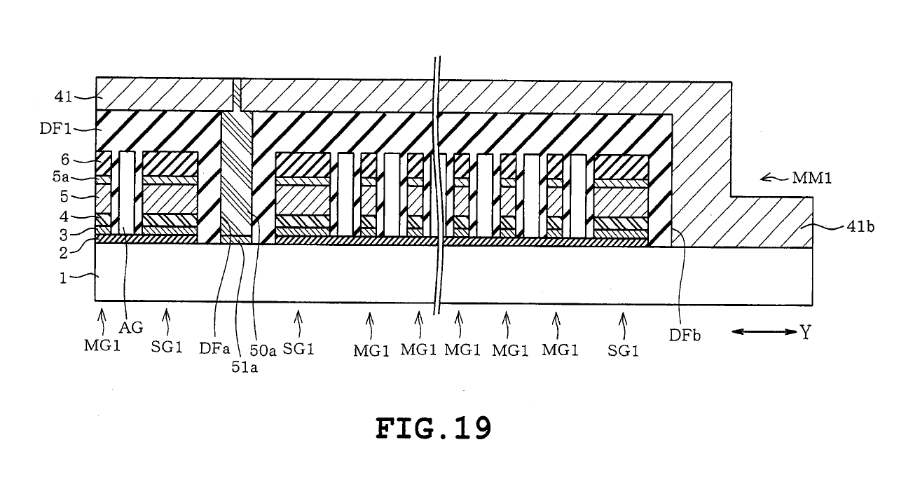

Next, as illustrated in FIG. 19, solid phase epitaxial growth (SPE) process is performed. Thus, the crystallization of amorphous silicon film 50 progresses from amorphous silicon film 50b portion contacting silicon substrate 1 at element region Sa1x portion with silicon substrate 1 serving as the seed. As a result, amorphous silicon film 50 is gradually crystallized into polycrystalline silicon film 41. In the solid phase epitaxial growth, crystallization also progresses from other contact regions not illustrated and is terminated before establishing contact at source line contact CS1 portion. The solid phase epitaxial growth may be progressed so that amorphous silicon film 50 is entirely crystallized into polycrystalline silicon film.

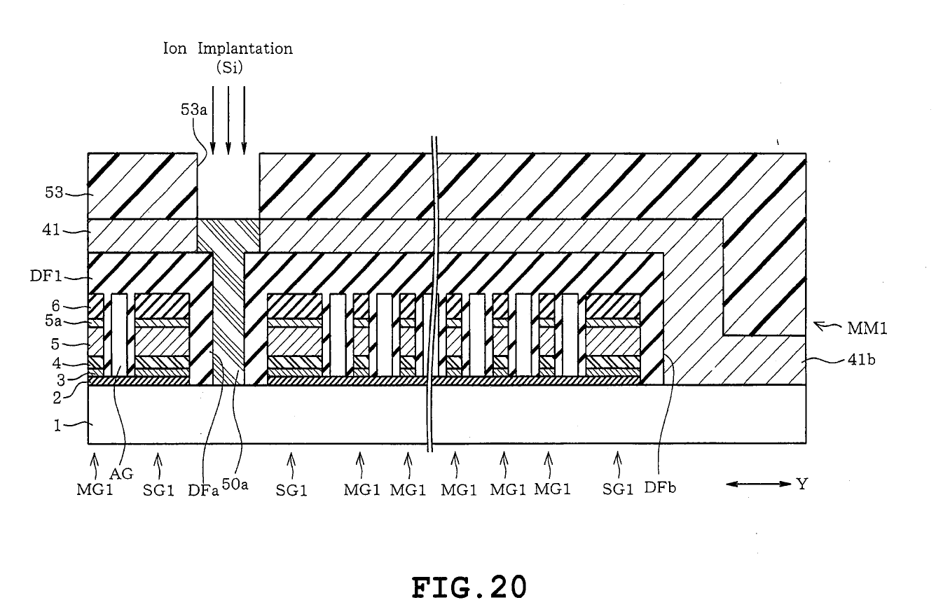

Next, as illustrated in FIG. 20, a photoresist is coated over the entire surface to form resist film 53 and opening 53a is provided therein to open source line contact CS1 portion. Then, ion implantation (mixing implantation) is carried out using resist film 53 as a mask. As a result, native oxide film 51a on the surface of silicon substrate 1 located in opening 53a dissipates from the surface portion of silicon substrate 1 by diffusing into the bulk interior. Thus, amorphous silicon film 50a of amorphous silicon film 50 located in opening DFa of interlayer insulating film DF1 is placed in direct contact with silicon substrate 1. Resist film 53 is removed thereafter. A portion of polycrystalline silicon film 41 exposed by opening 53a is also amorphized by the implanted ions and is transformed to amorphous silicon film 50a.

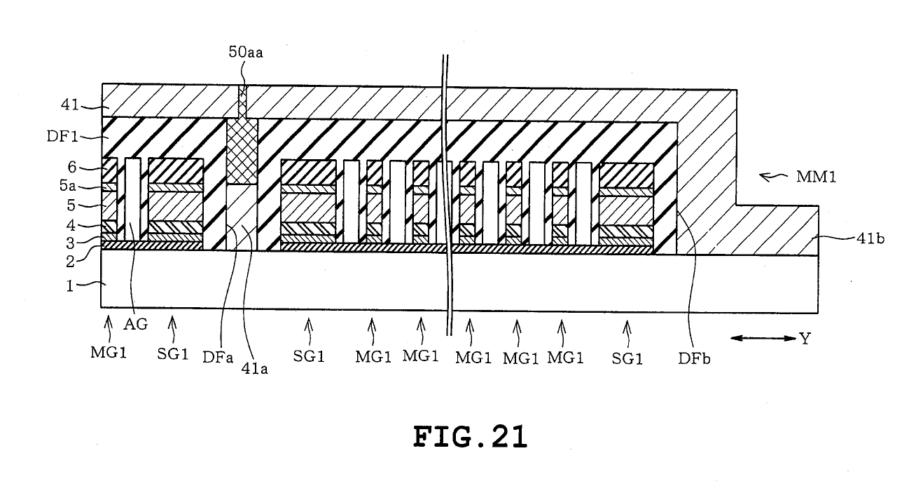

Next, as illustrated in FIG. 21, solid phase epitaxial growth (SPE) process is performed. Thus, the crystallization of amorphous silicon film 50a portion contacting silicon substrate 1 progresses with silicon substrate 1 serving as the seed. As a result, amorphous silicon film 50a is gradually crystallized into polycrystalline silicon film 41a. In the solid phase epitaxial growth, crystallization may not progress sufficiently because of the small contact area with silicon substrate 1 and thus, upper portion may remain as polycrystalline silicon film 50aa.

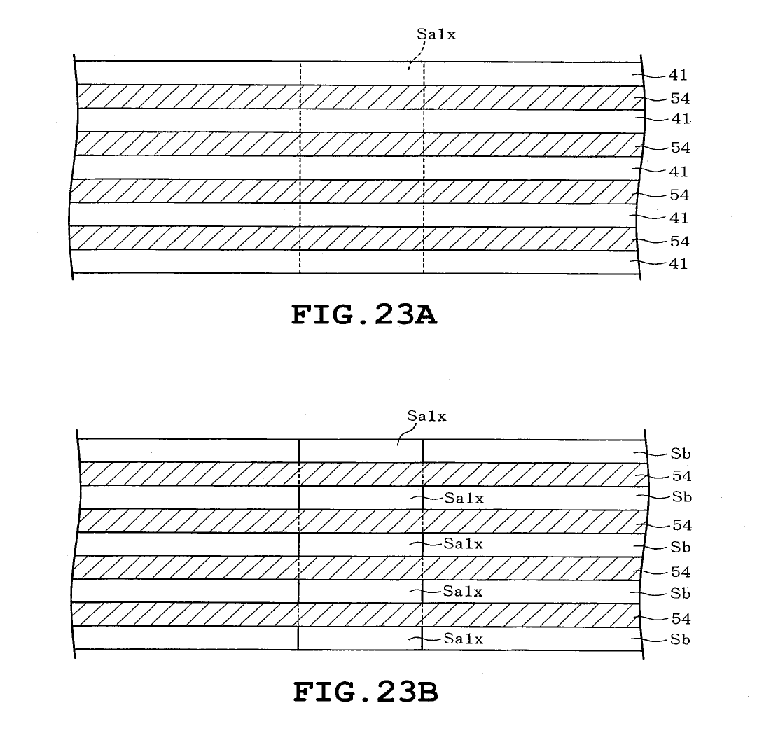

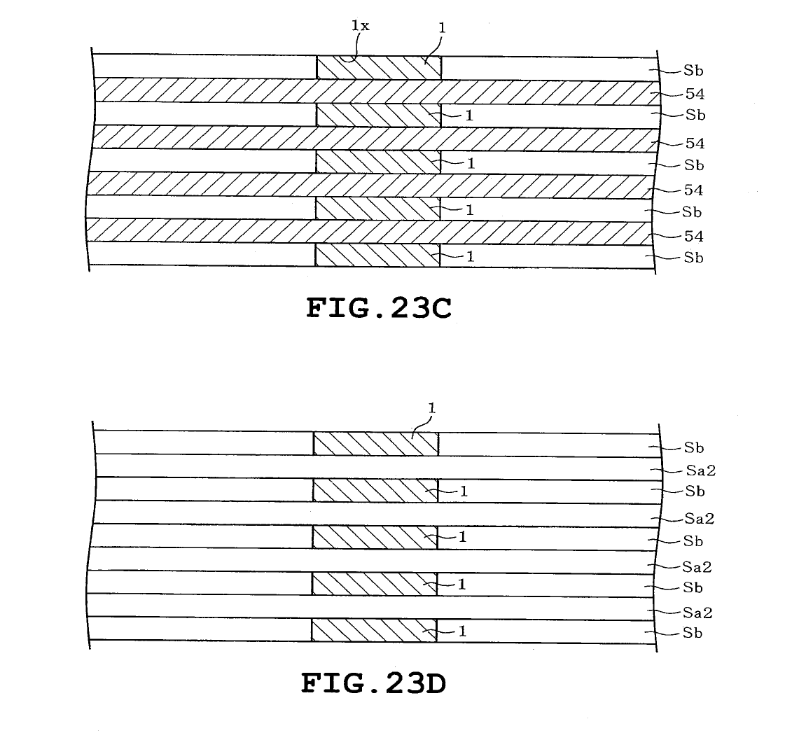

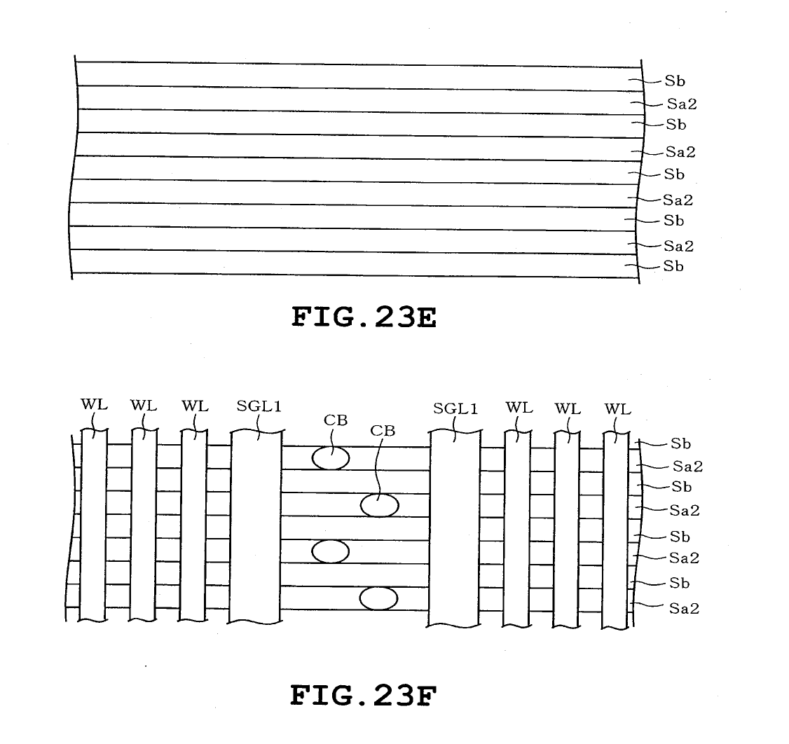

It is possible to crystallize a film formed originally as amorphous silicon film 50 into polycrystalline silicon film 41 by using solid phase epitaxial growth. The above described solid phase epitaxial growth is carried out based on a large area created by providing element region Sa1x in silicon substrate 1. Thus, it is required to split element region Sa1x into element regions Sa1 associated with each bit line. FIGS. 23A to 23F illustrate the splitting process.

Referring first to FIG. 23A, resist film 54 is coated above the upper surface of the crystallized polycrystalline silicon film 41 and is processed into a pattern for forming element region Sa2. The pattern of element region Sa2 is identical to the pattern of element region Sa1 of first layer MM1 provided in the underlying layer.

Then, as illustrated in FIG. 23B, polycrystalline silicon film 41 is etched using resist film 54 as a mask. Thus, polycrystalline silicon film 41 formed above element isolation region Sb is removed to result in polycrystalline silicon film 41 isolated into element regions Sa2 in the underlying layer of resist film 54. As a result, a surface of silicon substrate 1 serving as a portion of element region Sa1x used as the seed in the solid phase epitaxial growth is exposed.

Next, as illustrated in FIG. 23C, the etching further progresses from the above described state by a predetermined depth into silicon substrate 1 to form element isolation trenches 1x. Thus, silicon substrate 1 is exposed in the portions of element regions Sa1x.

Then, as illustrated in FIG. 23D, resist film 54 is removed. As a result, element regions Sa2 of second layer MM2 formed of isolated polycrystalline silicon film 41 appears to the surface.

Next, as illustrated in FIG. 23E, element isolation trenches 1x are filled with element isolation insulating film to form element isolation regions Sb. Thus, element regions Sa2 of second layer MM2 are isolated by element isolation regions Sb. Thereafter, the manufacturing process flow of second layer MM2 is carried out to provide memory gate electrode MG2, select gate electrode SG2, and the like, as well as word line WL2, select gate line SGL2, and bit line contact CB as illustrated in FIG. 23F.

The third embodiment described above provides polycrystalline silicon film 41 being crystallized after film formation to serve as element region Sa2 used as a channel layer of second layer MM2. It is thus, possible to increase the mobility of channel layer of second layer MM2 to facilitate flow of channel current and thereby improve device properties as compared to a film formed originally as a polycrystalline silicon film.

### Fourth Embodiment

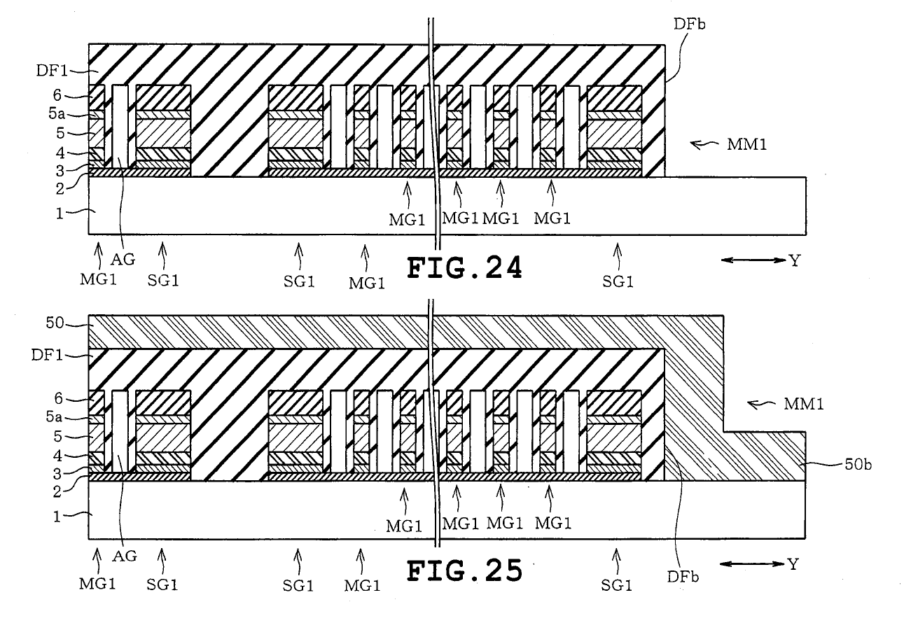

FIGS. 24 to 29 illustrate a fourth embodiment. This embodiment describes one example of the structures of the third embodiment being obtained by a different method. More specifically, this embodiment provides crystallized polycrystalline silicon film 41 described in the third embodiment by a different method. A description is given hereinafter focusing on the differences from the third embodiment with respect to the manufacturing process flow of polycrystalline silicon film 41.

First, a brief description will be given on the process steps for obtaining the structure illustrated in FIG. 24. Cell unit UC1 of first layer MM1 is formed above silicon substrate 1. Memory gate electrodes MG1 and select gate electrodes SG1 forming cell unit UC are substantially identical in structure. Then, interlayer insulating film DF1 is formed of insulating film for forming gaps, spacers, liner insulating films, and an interlayer insulating film or the like. Next, opening DFb is formed in interlayer insulating film DF1 located in the contact region disposed between select gate electrodes SG1 in bit line contact CB side. Element region Sa1x associated with bit line contact CB is formed in advance as described earlier.

Then, as illustrated in FIG. 25, amorphous silicon film 50 is formed above interlayer insulating film DF1. Amorphous silicon film 50 is also formed in opening DFb of interelectrode insulating film DF1 as amorphous silicon film 50b. Opening DFb opens element region Sa1x and thus, amorphous silicon film 50b is formed along the sidewalls of opening DFb and so as to cover the upper surface of element region Sa1x. Further, amorphous silicon film 50b is provided so as to contact silicon substrate 1 at the bottom surface of opening DFb of interlayer insulating film DF1.

Next, as illustrated in FIG. 26, solid phase epitaxial growth process is performed. Thus, the crystallization of amorphous silicon film 50 progresses from amorphous silicon film 50b portion contacting silicon substrate 1 at element region Sa1x portion with silicon substrate 1 serving as the seed. As a result, amorphous silicon film 50 is gradually crystallized into polycrystalline silicon film 41. In the solid phase epitaxial growth, crystallization also progresses from other contact regions not illustrated and forms an abutting portion at source line contact CS1 portion.

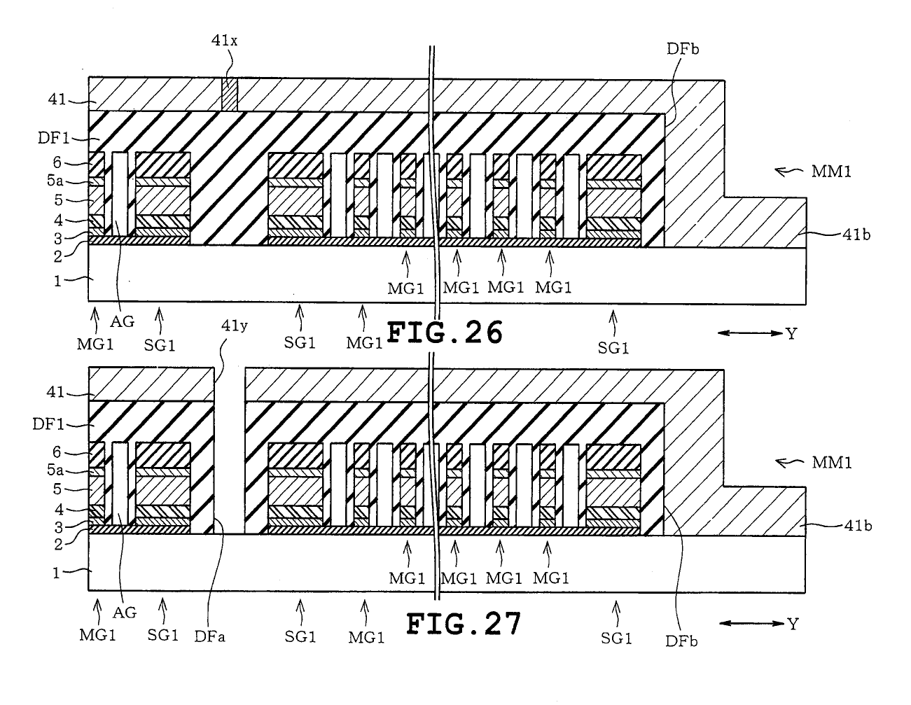

Then, as illustrated in FIG. 27, photoresist is patterned by lithography and etching is performed using the photoresist as a mask. Thus, opening 41y and DFa are formed into polycrystalline silicon film 41 and interlayer insulating film DF1 to expose the upper surface of silicon substrate 1 in the bottom surface portion within opening DFa.

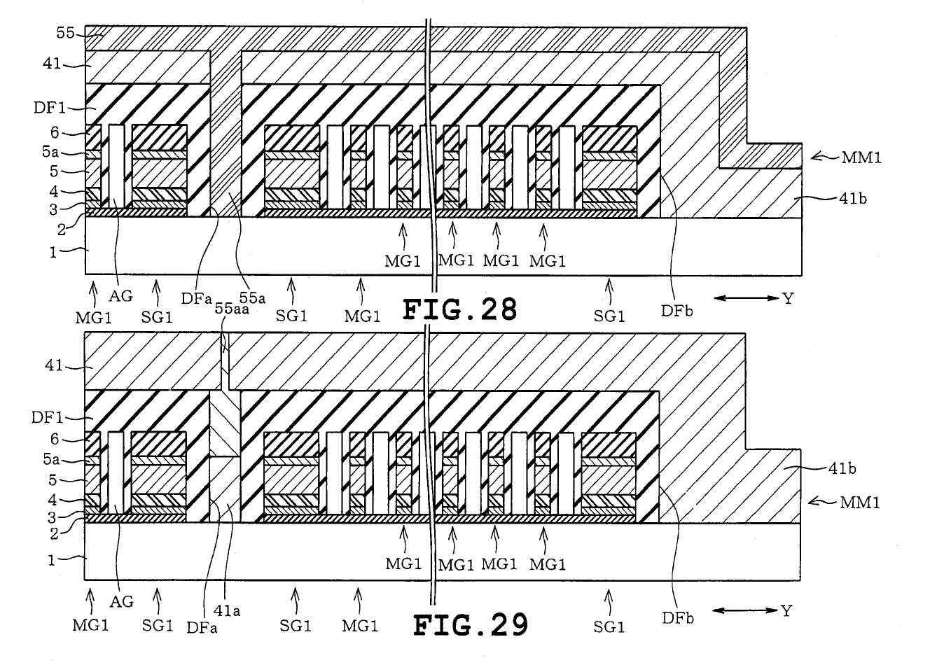

Next, as illustrated in FIG. 28, amorphous silicon film 55 is formed above the upper surface of polycrystalline silicon film 41. Amorphous silicon film 55 is provided so as to fill opening 41y of polycrystalline silicon film 41 and opening DFa of interlayer insulating film DF1. As a result, amorphous silicon film 55 contacts silicon substrate 1 within opening DFa of interlayer insulating film DF1.

Next, as illustrated in FIG. 29, solid phase epitaxial growth process is performed again. The solid phase epitaxial growth progresses the crystallization of amorphous silicon film 50 using the crystallized polycrystalline silicon film 41 formed in the underlying layer as a seed. Crystallization of amorphous silicon film 50b portion inside opening DFa of interlayer insulating film DF1 progresses upward by solid phase epitaxial growth from the portion contacting silicon substrate 1 at the bottom surface. In the solid phase epitaxial growth using silicon substrate 1 as the seed, crystallization progresses slowly because of the small contact area between amorphous silicon film 55 and silicon substrate 1. As a result, amorphous silicon film 55 within opening DFa of interlayer insulating film DF1 is formed as polycrystalline silicon film 41a crystallized to a mid portion thereof, and amorphous silicon film 55 located thereabove is an ordinary polycrystalline silicon film 55aa.

The fourth embodiment described above also achieves the effects similar to those of the third embodiment.

### Fifth Embodiment

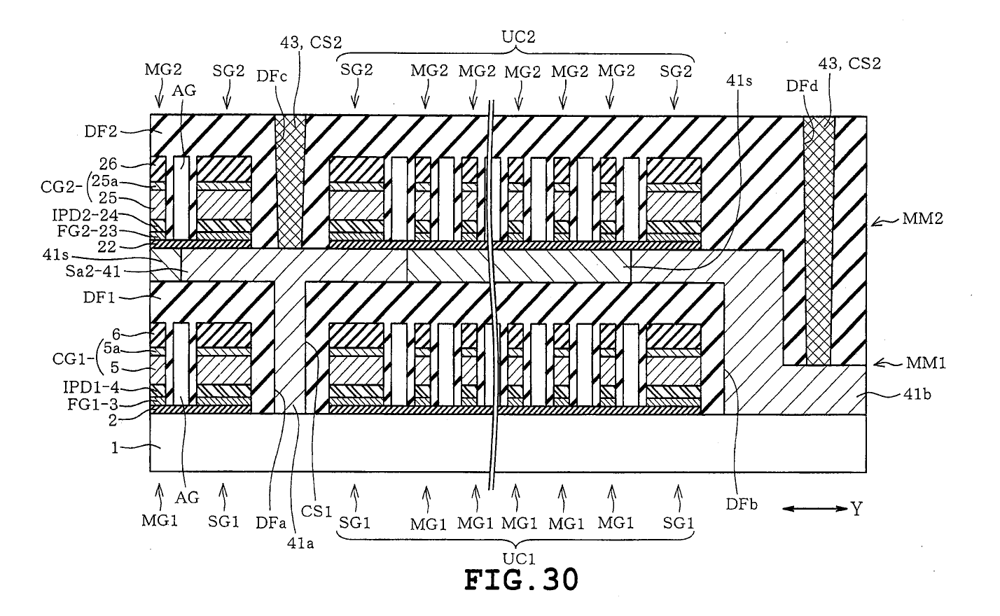

FIGS. 30 to 33 illustrate a fifth embodiment. This embodiment describes one example of the structures of the third embodiment being obtained by a different method. More specifically, this embodiment provides crystallized polycrystalline silicon film 41 described in the third embodiment by a different method.

In FIG. 30 illustrating the overall structure, cell unit UC1 of first MM1 layer being similar in structure to the third embodiment is provided above the upper surface of silicon substrate 1 serving as a semiconductor substrate, and these structures are covered by interlayer insulating film DF1.

In the contact region located between select gate electrodes SG1, contact plug CS1 is disposed to connect to source line SL. Contact plug CS1 is provided in contact hole DFa, extending through interlayer insulating film DF1 from the upper surface to the lower surface thereof. Contact plug CS1 is formed as polycrystalline silicon film 41a formed in one with the crystallized polycrystalline silicon film 41 serving as element regions Sa2 of second layer MM2.

Crystallized polycrystalline silicon film 41 serving as element regions Sa2 is formed above interlayer insulating film DF1. Polycrystalline silicon film 41 is substantially identical in shape such as width and spacing as element region Sa1 of silicon substrate 1. Further, polycrystalline silicon film 41 is plunged into first layer MM1 at the contact region located opening DFb of interlayer insulating film DF1 and contacts silicon substrate 1 in element region Sa1 portion.

Polycrystalline silicon film 41 is an amorphous silicon film at film formation and is crystallized into a polycrystalline silicon film through the later described process steps.

Polycrystalline silicon film 41 exhibits greater mobility in terms of electrical properties as compared to a film formed originally as polycrystalline silicon film. Polycrystalline silicon film 41 is provided as a crystallized film in the regions for forming select gate electrodes SG2, but is formed as polycrystalline silicon film 41s in which crystallization progresses poorly in regions for forming memory gate electrodes MG2.

Second layer MM2 is disposed above polycrystalline silicon film 41. Interlayer insulating film DF2 is provided so as to cover memory gate electrodes MG2 and select gate electrodes SG2 and so as to fill the contact regions. In the contact region located between select gate electrodes SG2, contact plug CB is disposed to connect to bit line BL being shared with first layer MM1 and well as contact plug CS2 of second layer MM2. Contact plug CB is provided in contact hole DFd, extending from the upper surface of interlayer insulating film DF2 to the upper surface of polycrystalline silicon film 41. Contact plug CB is disposed so as to contact the upper surface of polycrystalline silicon film 41a where polycrystalline silicon film 41 contacts silicon substrate 1. Contact plug CB is formed by filling contact hole DFd with a metal film 42 such as tungsten (W).

Further, Contact plug CS2 is provided in contact hole DFc, extending from the upper surface of interlayer insulating film DF2 to the upper surface of polycrystalline silicon film 41. Contact plug CS2 is disposed so as to contact the upper surface of polycrystalline silicon film 41. Contact plug CS2 is formed by filling contact hole DFc with a metal film 43 such as tungsten (W).

Next, a description will be given on the process flow for forming polycrystalline silicon film 41 focusing on the differences from the third embodiment.

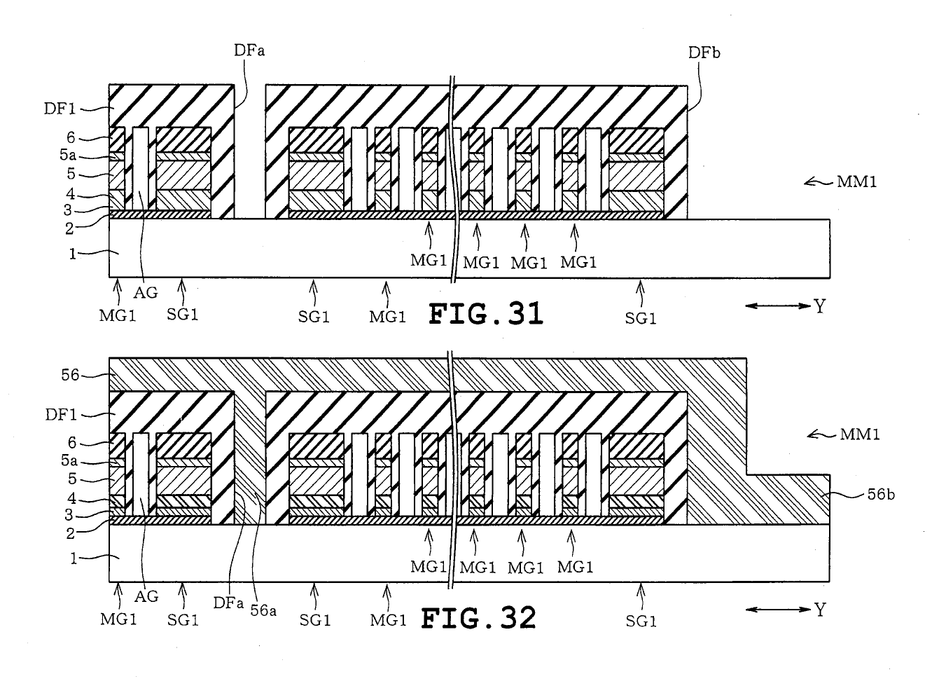

The process steps for obtaining the structure illustrated in FIG. 31 is identical to those of the third embodiment and thus, will not be described. In the illustrated state, element regions Sa1 are formed in silicon substrate 1 and memory gate electrodes MG1 and select gate electrodes SG1 are formed in element regions Sa1. Interlayer insulating film DF1 is formed so as to cover gate electrodes MG1 and SG1.

In the illustrated state, openings DFa and DFb are formed into interlayer insulating film DF1 located in the two contact regions located between select gate electrodes SG1. Opening DFa for source line contact CS1 is formed as a trench having a predetermined width in the Y direction and extending in the X direction. Opening DFb corresponding to bit line contact CB opens up the wide region between select gate electrodes SG1.

Then, as illustrated in FIG. 32, amorphous silicon film 56 is formed above interlayer insulating film DF1. Amorphous silicon film 56 is formed in opening DFa and opening DFb of interelectrode insulating film DF1 as amorphous silicon films 56a and 56b. Opening DFb opens element region Sa1x and thus, amorphous silicon film 56b is formed so as to cover the sidewalls of opening DFb as well as the upper surface of element region Sa1x. Further, amorphous silicon films 56b is provided so as to contact silicon substrate 1 at the bottom surface of opening DFb of interlayer insulating film DF1.

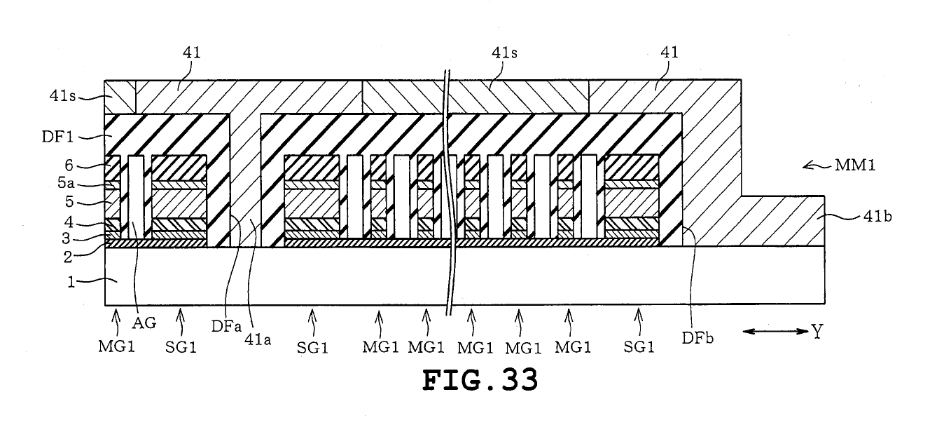

Next, as illustrated in FIG. 33, solid phase epitaxial growth process is performed. As a result, the crystallization of amorphous silicon film 56a within opening DFa of interlayer insulating film progresses upward using silicon substrate 1 at the bottom surface as the seed. Crystallization of amorphous silicon film 56b portion contacting silicon substrate 1 at element region Sa1x portion also progresses using silicon substrate as the seed.

As a result, amorphous silicon film 56 is gradually crystallized into polycrystalline silicon film 41. Because crystallization progresses simultaneously from amorphous silicon films 56a and 56b in this example of solid phase epitaxial growth process, it is possible to achieve prompt crystallization. Further, by progressing crystallization starting from the two contact regions, it is possible to prioritize the crystallization of amorphous silicon film 56 at the lower portions of select gate electrodes SG2 where high mobility is required. An ordinary polycrystalline silicon film 41s may be formed at the lower portions of memory gate electrodes MG2.

The fifth embodiment described above also achieves the effects similar to those of the third embodiment.

### Sixth Embodiment

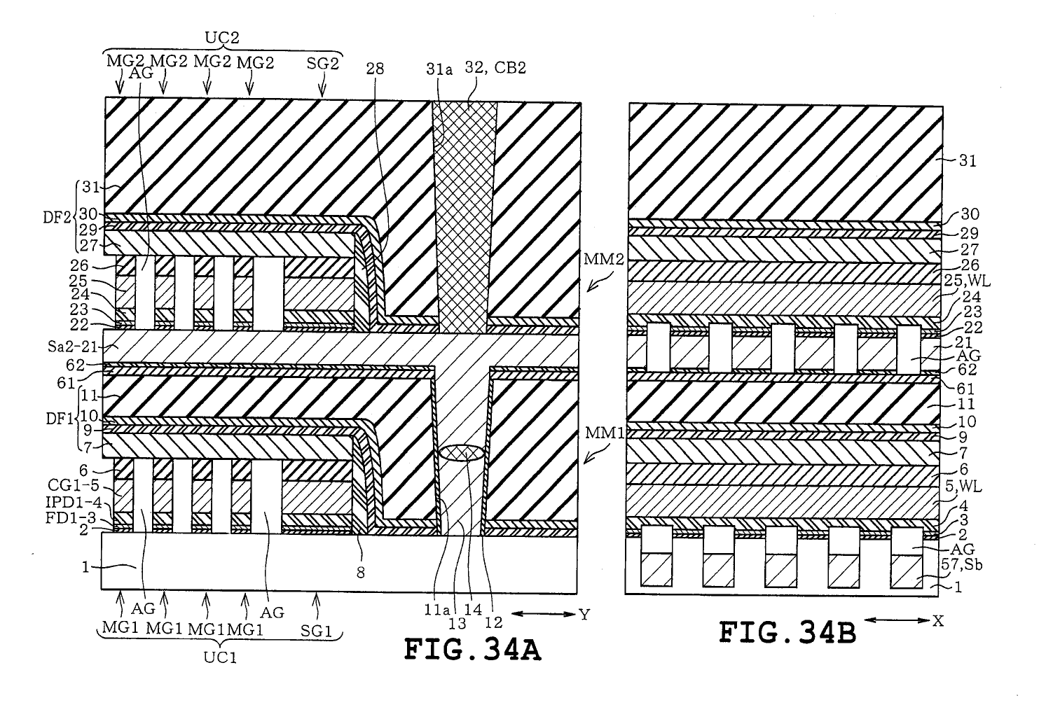

FIGS. 34A and 34B illustrated a sixth embodiment. This embodiment is effective when applied to a structure in which air gap AG is also formed in element isolation insulating region Sb in a structure described in the first embodiment in which second layer MM2 or the like is stacked above first layer MM1.

FIG. 34A corresponds to FIG. 4 of the first embodiment and is one example of a vertical cross-sectional side view taken along line 3-3 of FIG. 2. Further, FIG. 34B is one example of a vertical cross-sectional side view taken along line 34B-34B of FIG. 2.

As illustrated in FIGS. 34A and 34B, the upper portions of the portions where element isolation insulating film 57 of first layer MM1 are provided are removed by etching to provide air gaps AG in which the gaps serve as dielectrics. Thus, capacitive coupling between the cells is reduced in the STI portion as well. The structure described above forms air gaps AG in second layer MM2 as well by filling sacrificial film or the like instead of an insulating film between the isolated element forming regions Sa2 comprising crystallized polycrystalline silicon film 41 and removing the sacrificial film later in the process flow. When etching the sacrificial film provided in the element isolation regions Sb of second layer MM2, intrusion of chemical liquid in first layer MM1 side causes unwanted damages.

The present embodiment provides silicon nitride film 61 and silicon oxide film 62 serving as an underlay for forming polycrystalline silicon film 41 serving as element region Sa2 of second layer MM2 in order to resolve such problems.

It is thus, possible to prevent damages to first layer MM1 caused by intrusion of chemical liquids during the manufacturing process flow of a structure provided with air gaps AG in element isolation region Sb.

In the above described structure, alumina (Al₂O₃) film may be used instead of silicon nitride film 61.

### Seventh Embodiment

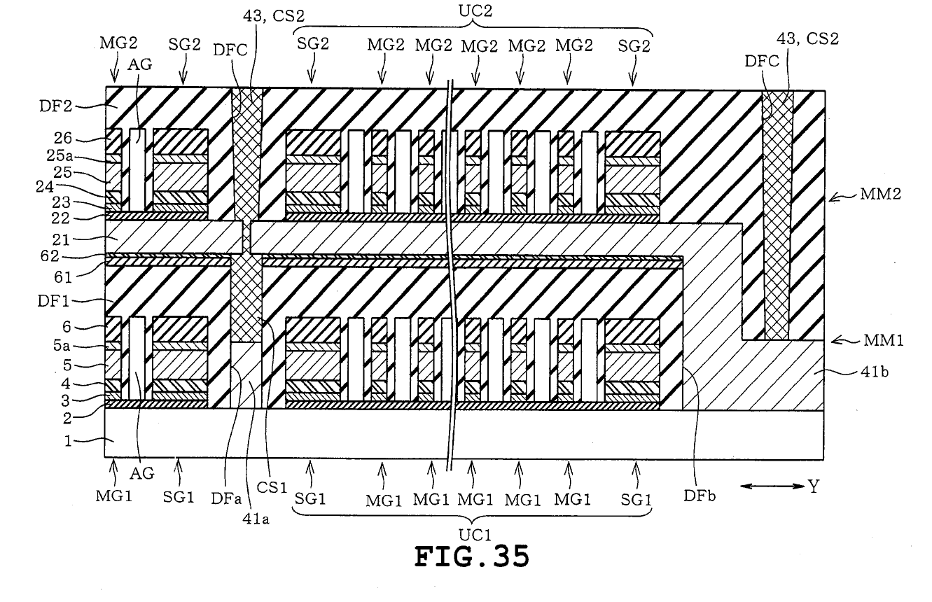

FIG. 35 illustrates a seventh embodiment. This embodiment is effective when applied to a structure in which air gap AG is also formed in element isolation insulating region Sb in a structure described in the first embodiment in which second layer MM2 or the like is stacked above first layer MM1.

Though the provision of air gaps AG in element isolation region Sb is not illustrated in FIG. 35, air gaps AG may be provided in the similar manner as the sixth embodiment. In such structure, silicon nitride film 61 and silicon oxide film 62 serving as an underlay for forming polycrystalline silicon film 41 serving as element region Sa2 of second layer MM2 are provided as was the case in the sixth embodiment. It is thus, possible to prevent damages to first layer MM1 caused by intrusion of chemical liquids during the manufacturing process flow of a structure provided with air gaps AG in element isolation region Sb.

### Other Embodiments

The foregoing embodiments may be modified as follows.

Description was given through an application of a double layer of first layer MM1 and second layer MM2; however, the same is applicable to applications forming a polycrystalline silicon film serving as element region Sa in second layer MM2 or higher levels in a structure provided with three or more layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a semiconductor substrate;
a first layer memory cell having the semiconductor substrate serving as a channel layer;
a semiconductor layer provided along the first layer memory cell via an insulating film; and
a second layer memory cell having the semiconductor layer serving as a channel layer,
the semiconductor layer of the second memory cell layer comprises a polycrystalline silicon film including a single crystal region.

2. The semiconductor storage device according to claim 1, wherein the semiconductor layer contains a metal.

3. The semiconductor storage device according to claim 1, further comprising a metal silicide layer in a contact portion between the semiconductor layer and the semiconductor substrate.

4. The semiconductor storage device according to claim 3, wherein the metal silicide layer is provided inside a contact plug connected to the first layer memory cell.

5. The semiconductor storage device according to claim 3, wherein the metal silicide layer is a nickel silicide.

6. The semiconductor storage device according to claim 3, wherein the semiconductor layer is a polycrystalline silicon film single crystallized using metal as a catalyst.

7. The semiconductor storage device according to claim 1, wherein the semiconductor layer is disposed so as to contact the semiconductor substrate.

8. The semiconductor storage device according to claim 7, wherein the semiconductor layer is a polycrystalline silicon single crystallized by solid phase epitaxial growth.

9. The semiconductor storage device according to claim 7, wherein the semiconductor layer is provided so as to contact a region for forming a contact in the semiconductor substrate.

10. The semiconductor storage device according to claim 7, wherein at least a channel portion of a select transistor provided at least in the second layer memory cell is single crystallized.

11. The semiconductor storage device according to claim 1, further comprising a silicon nitride film provided between the first layer memory cell and the second layer memory cell.

12. The semiconductor storage device according to claim 1, further comprising a alumina film provided between the first layer memory cell and the second layer memory cell.

13. A method of manufacturing a semiconductor storage device comprising:
forming a first layer memory cell above a semiconductor substrate serving as a channel layer;
forming an insulating film above the first layer memory cell;
forming a semiconductor layer via the insulating film; and
forming a second layer memory cell above the semiconductor layer, the semiconductor layer serving as a channel layer of the second layer memory cell.

14. The method of manufacturing a semiconductor storage device according to claim 13, wherein the semiconductor layer is formed by forming an amorphous semiconductor film after forming the first layer memory cell and the insulating film, forming a metal film portion contacting a portion of the amorphous semiconductor film, and crystallizing the amorphous semiconductor film by thermal treatment using the metal film portion as the catalyst to form the semiconductor layer.

15. The method of manufacturing a semiconductor storage device according to claim 14, wherein the metal film portion is formed of a silicide film formed at a contact portion of the first layer memory cell.

16. The method of manufacturing a semiconductor storage device according to claim 13, wherein the semiconductor layer is formed by exposing a portion of the semiconductor substrate after forming the first layer memory cell and the insulating film, forming an amorphous semiconductor film so as to contact a portion of a surface of the semiconductor substrate, crystallizing the amorphous semiconductor film by solid phase epitaxial growth in which the semiconductor substrate serves as a seed to form the semiconductor layer.

17. The method of manufacturing a semiconductor storage device according to claim 16, wherein a contact portion of the first layer memory cell is exposed to serve as a portion of a surface of the semiconductor substrate.

18. The method of manufacturing a semiconductor storage device according to claim 13, wherein a plurality of interconnected contact portions of the first layer memory cell are exposed to serve as a portion of a surface of the semiconductor substrate, and the interconnected contact portions of the first memory cell layer are divided after forming the semiconductor layer.

19. The method of manufacturing a semiconductor storage device according to claim 17, wherein a gap is formed by forming a silicon nitride film above the insulating film, forming the semiconductor layer above the silicon nitride film, dividing the semiconductor layer into a plurality of channel regions and filling an isolation insulating film, forming a second layer memory cell above the semiconductor layer, and treating the isolation insulating film of the semiconductor layer with a chemical liquid.

20. The method of manufacturing a semiconductor storage device according to claim 17, wherein a gap is formed by forming a alumina film above the insulating film, forming the semiconductor layer above the alumina film, dividing the semiconductor layer into a plurality of channel regions and filling an isolation insulating film, forming a second layer memory cell above the semiconductor layer, and treating the isolation insulating film of the semiconductor layer with a chemical liquid.
